(19) United States
(12) Patent Application Publication
(10) Pub. No.: US 2025/0344374 A1
(43) Pub. Date: Nov. 6, 2025

(54) SEMICONDUCTOR DEVICES

(71) Applicant: Samsung Electronics Co., Ltd., Suwon-si (KR)

(72) Inventors: Hongjun LEE, Suwon-si (KR); Keunnam KIM, Suwon-si (KR); Yongkwan KIM, Suwon-si (KR); Huijung KIM, Suwon-si (KR)

(73) Assignee: Samsung Electronics Co., Ltd., Suwon-si (KR)

(21) Appl. No.: 19/053,645

(22) Filed: Feb. 14, 2025

(30) Foreign Application Priority Data
May 2, 2024 (KR) 10-2024-0058259

(51) Int. Cl. H10B 12/00

(52) U.S. Cl. CPC H10B 12/482; H10B 12/315

(57) ABSTRACT

A semiconductor device includes an active pattern on a substrate, the substrate including a cell array region and an extension region, the extension region being at opposite sides in a first direction of the cell array region, a bit line structure extending in the first direction on the active pattern, and a spacer structure on a sidewall of the bit line structure in a second direction, the second direction being perpendicular to the first direction. A first thickness of a first portion of the spacer structure on the extension region of the substrate in the second direction is greater than a second thickness of a second portion of the spacer structure on the cell array region of the substrate in the second direction.

### CROSS-REFERENCE TO RELATED APPLICATION

This application claims priority under 35 U.S.C. § 119 to Korean Patent Application No. 10-2024-0058259 filed on May 2, 2024 in the Korean Intellectual Property Office, the disclosure of which is hereby incorporated by reference in its entirety.

### BACKGROUND OF THE INVENTION

Various example embodiments of the present disclosure relate to a semiconductor device. More particularly, various example embodiments of the present disclosure relate to a DRAM device.

A DRAM device may include a bit line structure and a spacer covering a sidewall of the bit line structure. During an anisotropic etching process to form the spacer, an end portion of the bit line structure, which is relatively weak, may be damaged.

### SUMMARY

Various example embodiments provide a semiconductor device having improved electrical characteristics.

According to various example embodiments of the inventive concepts a semiconductor device may include an active pattern on a substrate, the substrate including a cell array region and an extension region, the extension region being at opposite sides in a first direction of the cell array region, a bit line structure extending in the first direction on the active pattern, and a spacer structure on a sidewall of the bit line structure in a second direction, the second direction being perpendicular to the first direction. A first thickness of a first portion of the spacer structure on the extension region of the substrate in the second direction is greater than a second thickness of a second portion of the spacer structure on the cell array region of the substrate in the second direction.

According to various example embodiments of the inventive concepts a semiconductor device may include an active pattern on a substrate, the substrate including a cell array region and an extension region, the extension region being at opposite sides in a first direction of the cell array region, a bit line structure extending in the first direction on the active pattern, and a spacer structure on a sidewall of the bit line structure in a second direction, the second direction being perpendicular to the first direction. A first portion of the spacer structure on the extension region of the substrate includes a first spacer, a second spacer, a third spacer, an insulation layer, and a fourth spacer sequentially stacked on the sidewall of the bit line structure in the second direction, and a second portion of the spacer structure on the cell array region of the substrate includes the first spacer, the second spacer, the third spacer, and the fourth spacer sequentially stacked on the sidewall of the bit line structure in the second direction.

According to various example embodiments of the inventive concepts a semiconductor device may include active patterns on a substrate, the substrate including a cell array region and an extension region, the extension region being at opposite sides in a first direction of the cell array region, the active patterns spaced apart from each other in the first direction and a second direction, the second direction being perpendicular to the first direction, and bit line structures, and each of the bit line structures including an extension portion extending in the first direction on the cell array region of the substrate and overlapping central portions of the active patterns arranged in the first direction, a pad portion on the extension region of the substrate, the pad portion contacting an end of the extension portion in the first direction, spacer structures on sidewalls of the bit line structures, respectively, and contact plug structures on end portions of the active patterns, respectively. A width of the pad portion of each of the bit line structures in the second direction is greater than a width of the extension portion of the bit line structures in the second direction, and a first thickness of a first portion of each of the spacer structures on the extension region of the substrate in the second direction is greater than a second thickness of a second portion of each of the spacer structures on the cell array region of the substrate in the second direction.

In the method of manufacturing a semiconductor device according to various example embodiments of the inventive concepts, a spacer layer may be formed on a sidewall of the bit line, a portion of the spacer layer on a relatively weak end portion of the bit line structure may be covered, and only an exposed portion of the spacer layer may be anisotropically etched. That is, the anisotropic etching process may not be performed on the spacer layer on the end portion of the bit line structure, and thus, the end portion of the bit line structure may be not damaged.

Alternatively, before anisotropically etching the spacer layer, an insulation layer may be additionally formed on the end portion of the bit line structure. Accordingly, the end potion of the bit line structure may be protected by the additionally formed insulation layer during the anisotropic etching process of the spacer layer.

### BRIEF DESCRIPTION OF THE DRAWINGS

FIGS. 1 to 64 are plan views and cross-sectional views illustrating a method of manufacturing a semiconductor device according to various example embodiments.

FIGS. 65 to 92 are plan views and cross-sectional views illustrating a method of manufacturing a semiconductor device according to various example embodiments.

### DETAILED DESCRIPTION

The above and other aspects and features of a decoupling capacitor structure and a method of forming the same, and a semiconductor device including the decoupling capacitor structure and a method of manufacturing the same in accordance with various example embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer, or section discussed below could be termed a second or third element, component, region, layer, or section without departing from the teachings of inventive concepts.

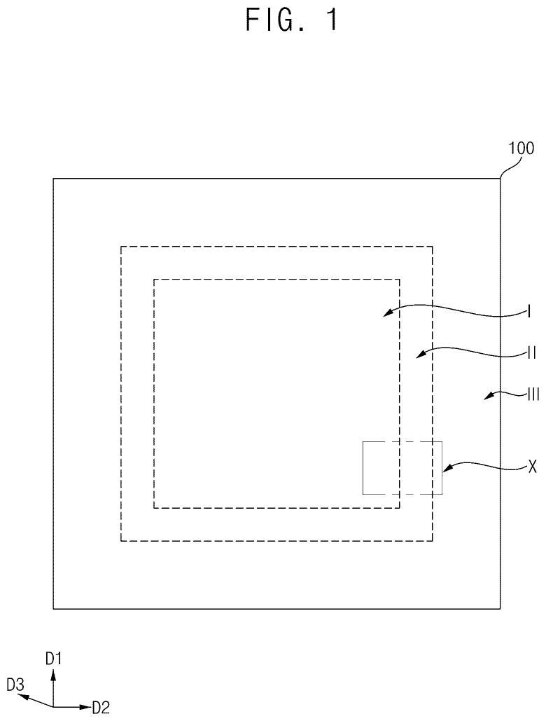

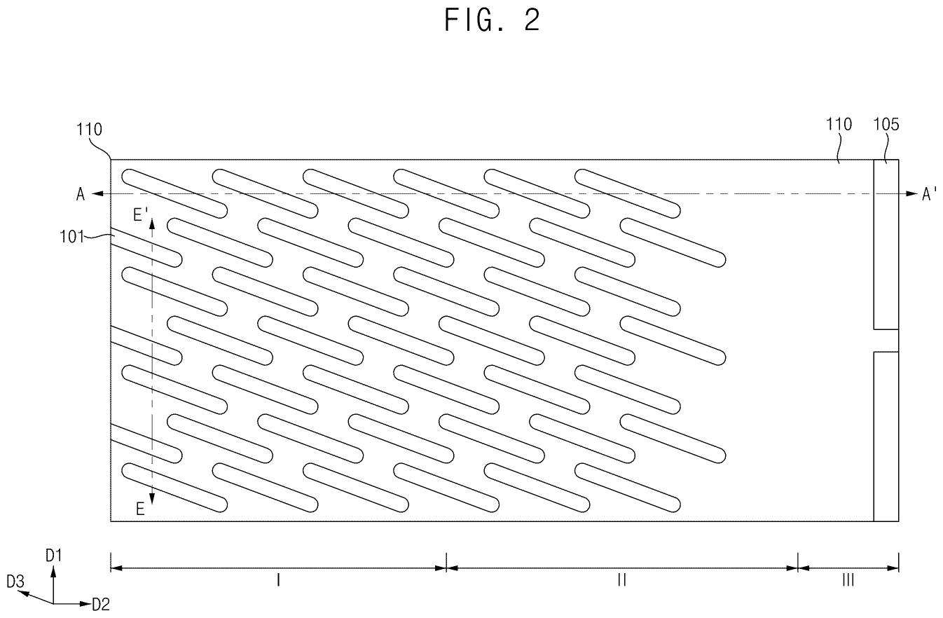

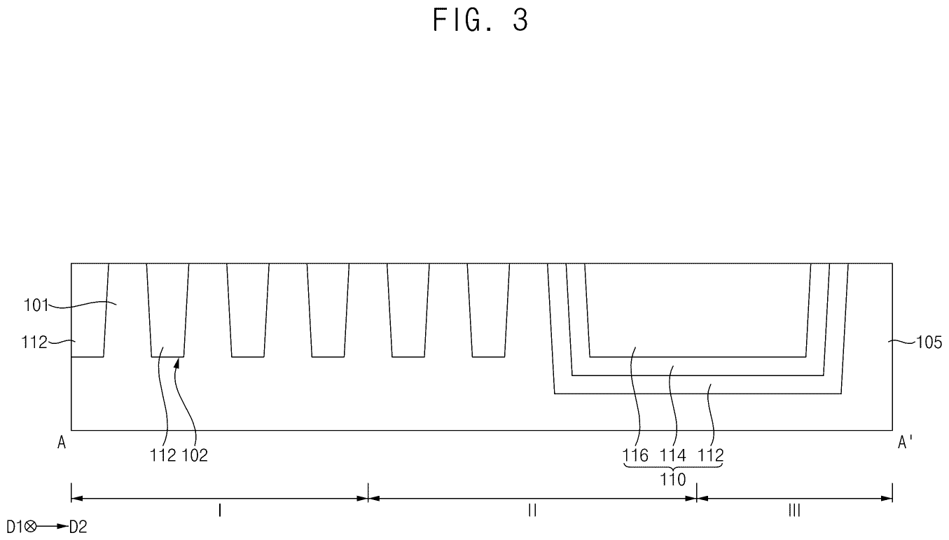

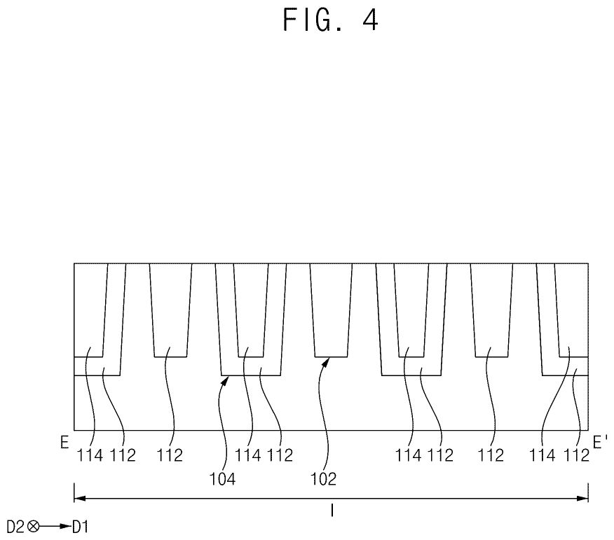

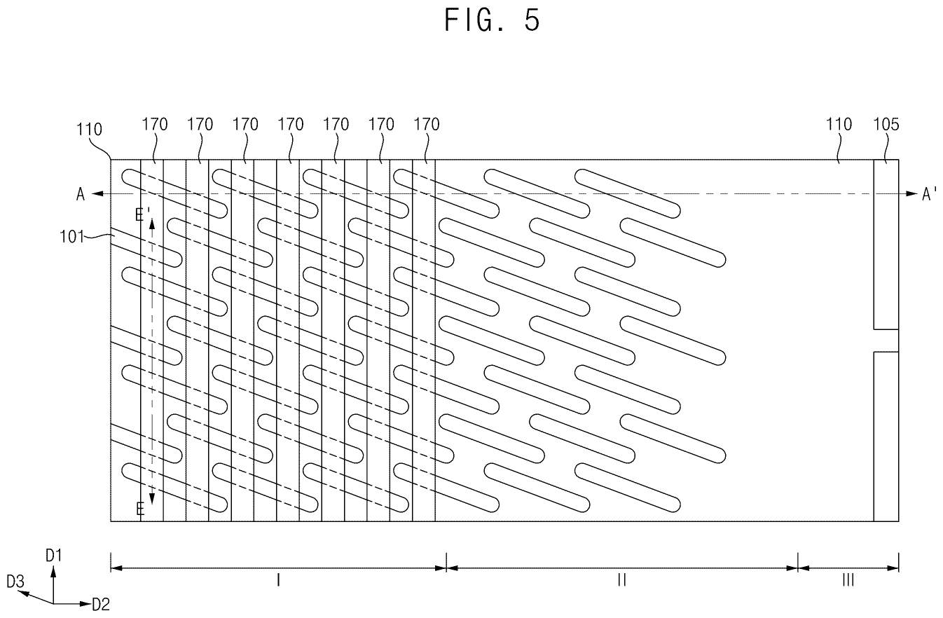

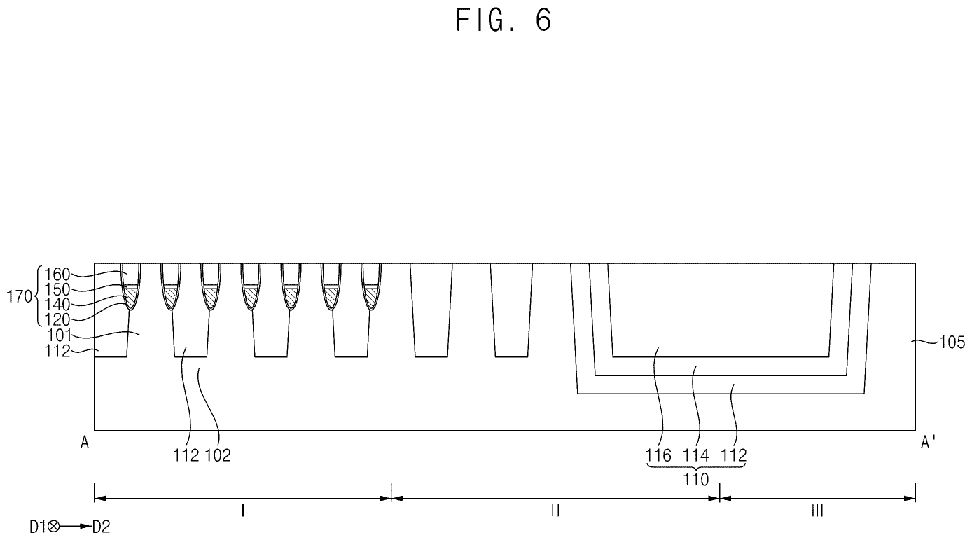

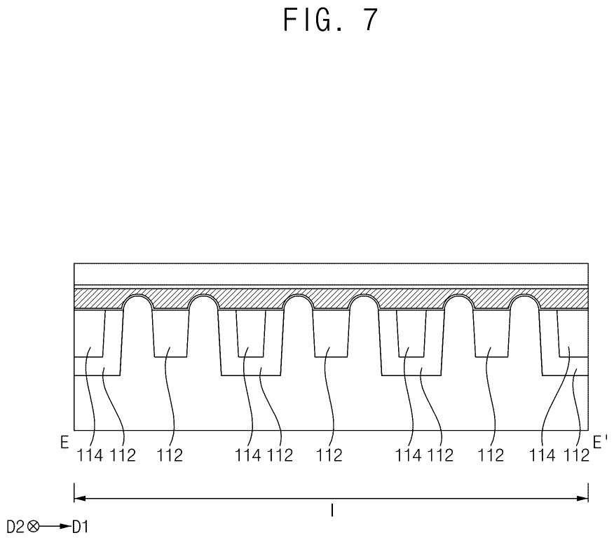

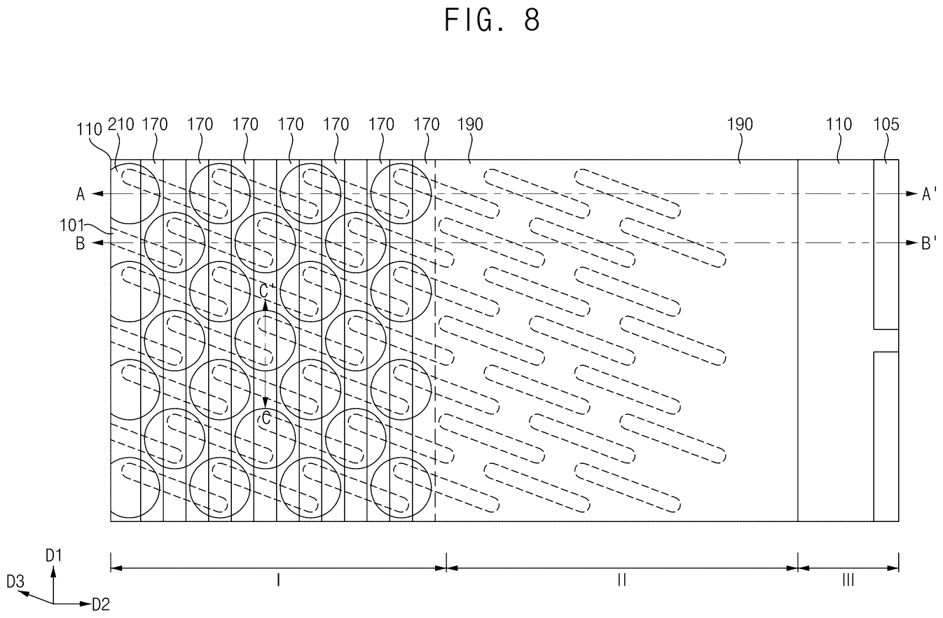

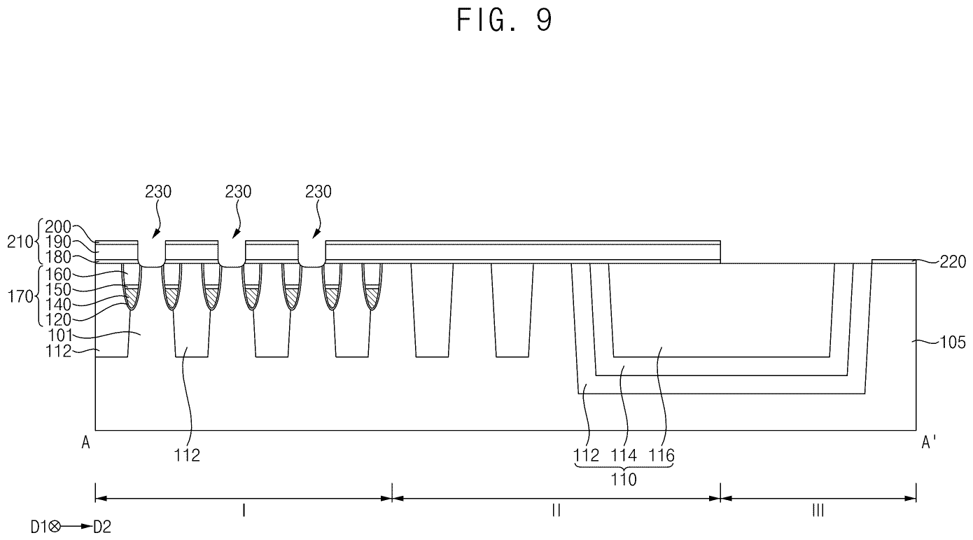

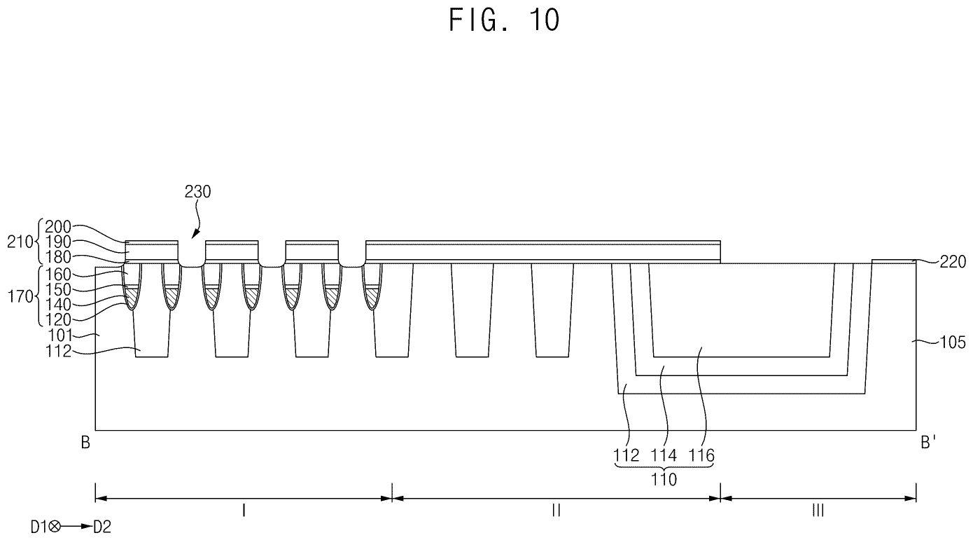

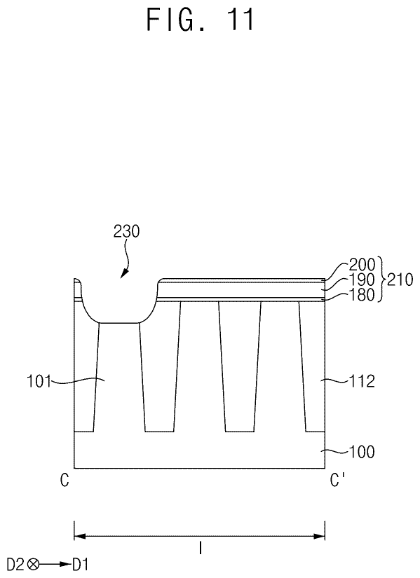

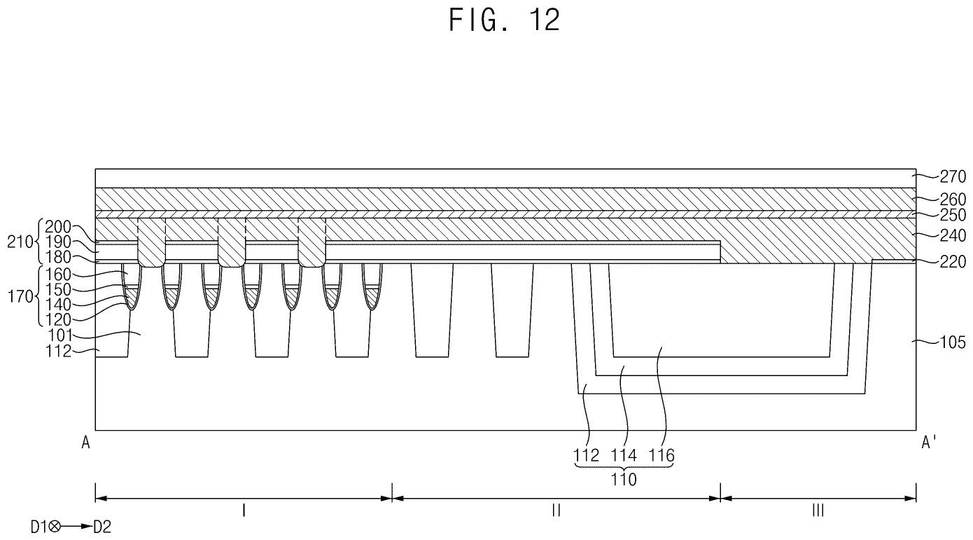

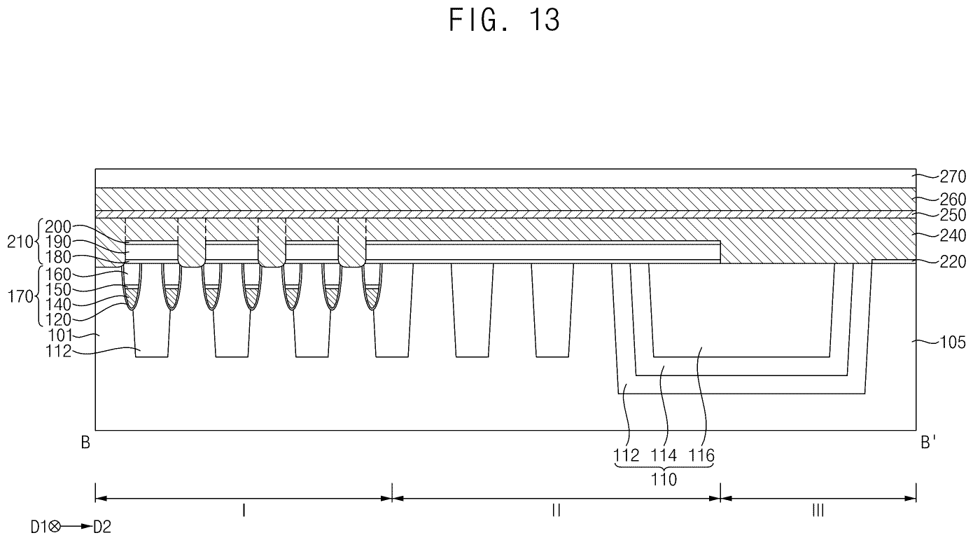

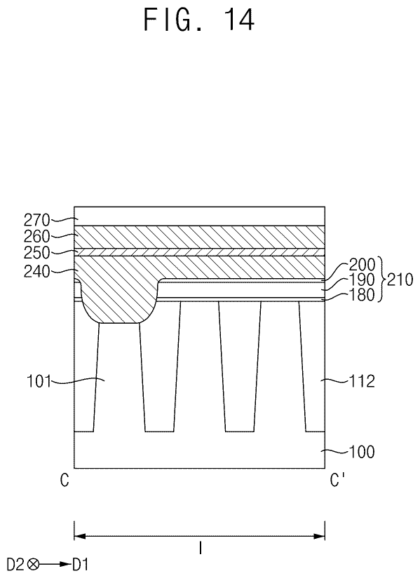

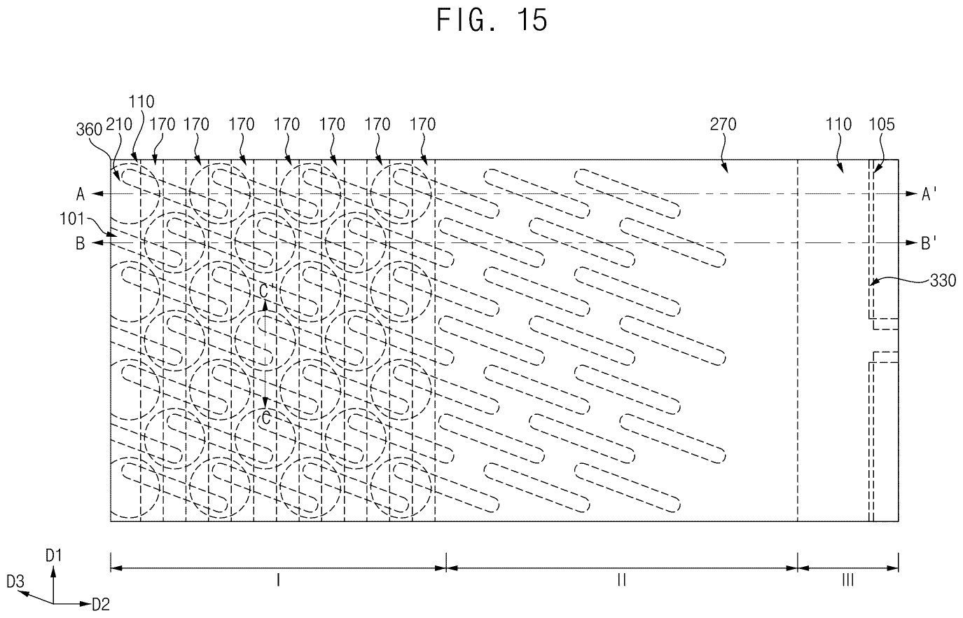

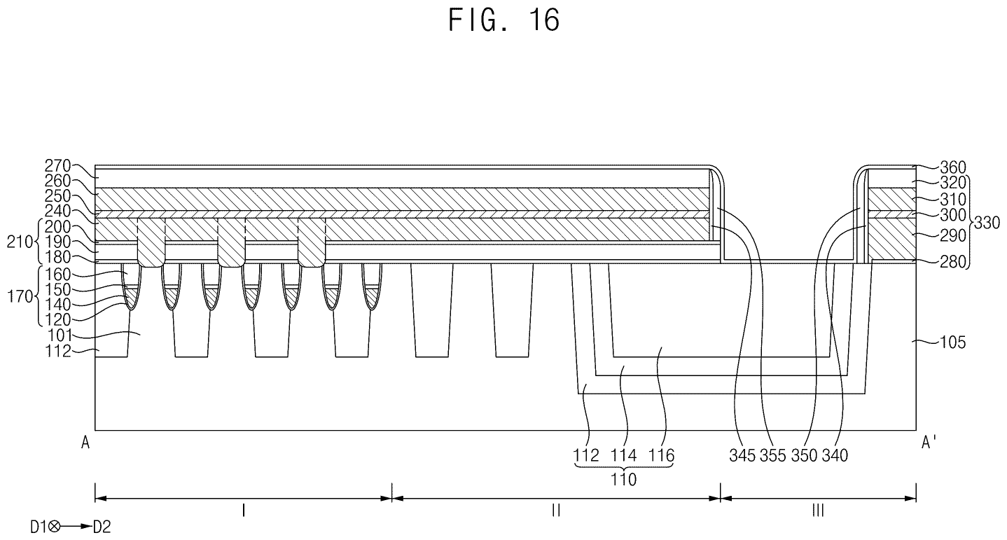

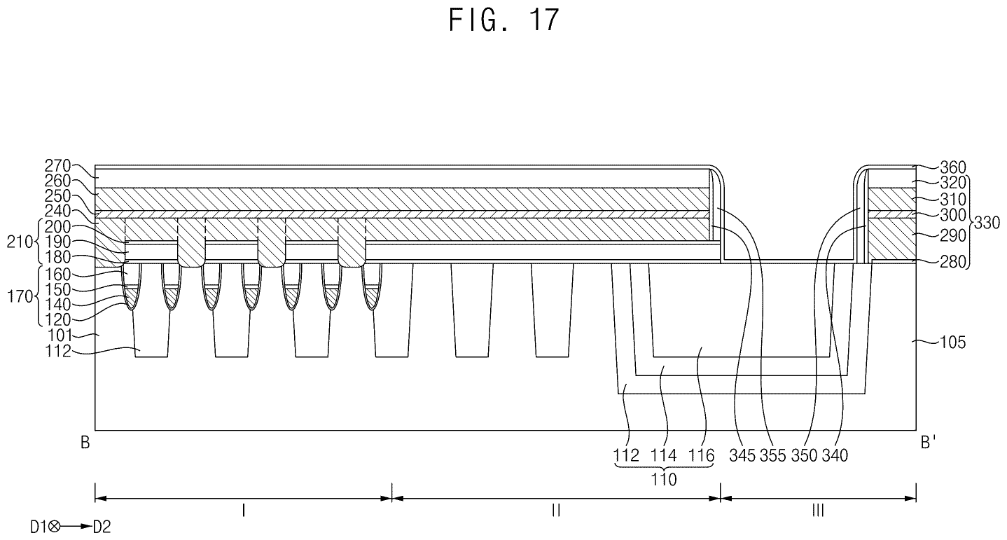

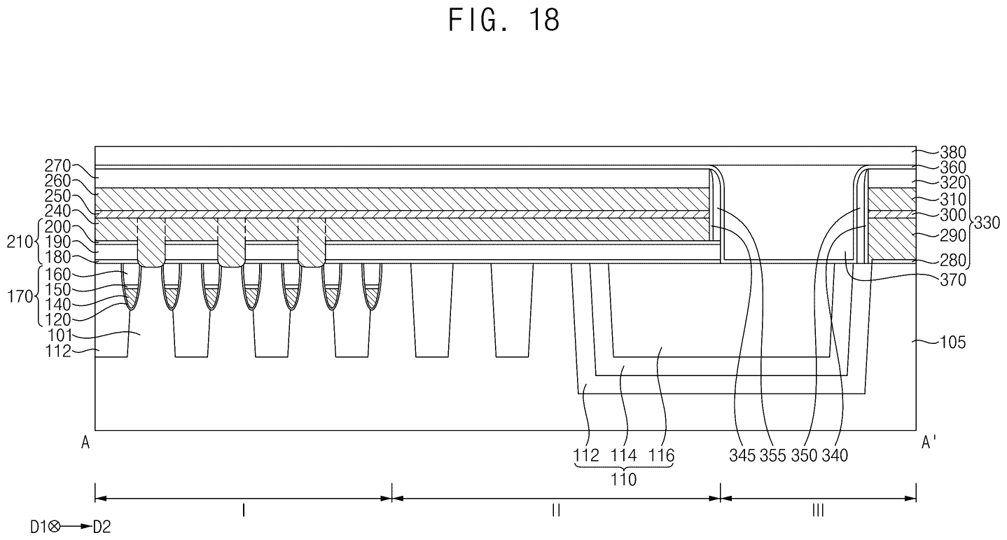

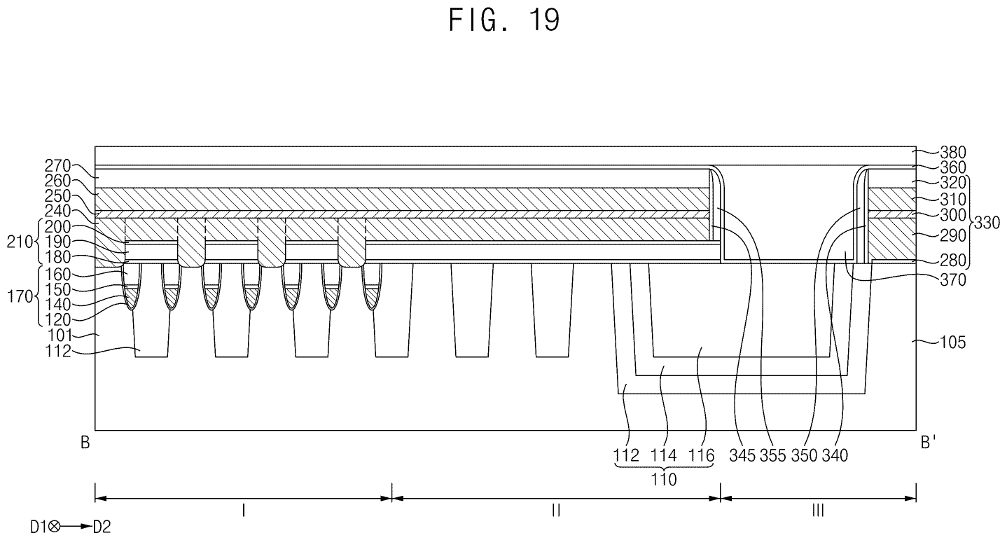

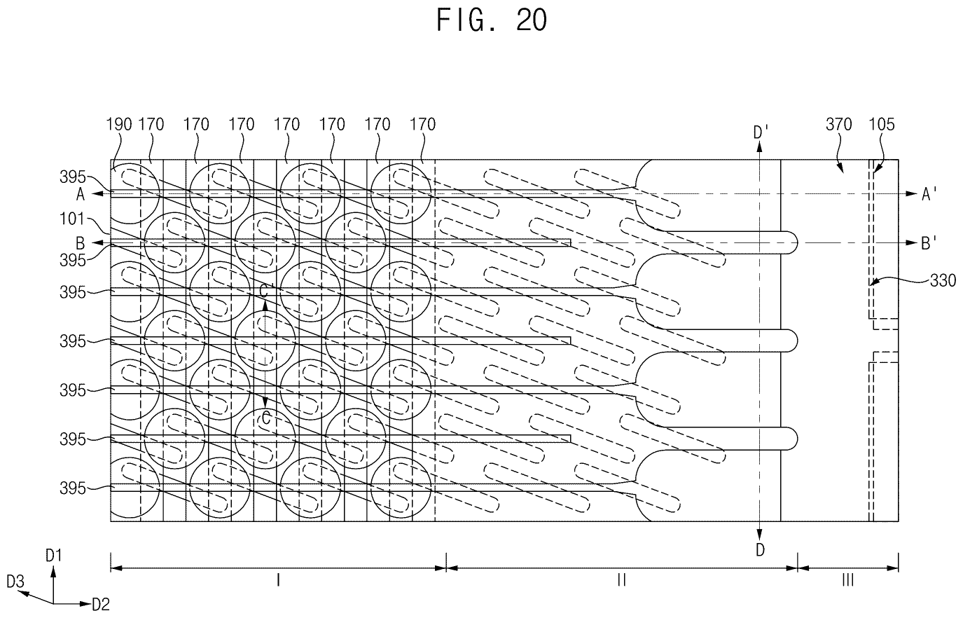

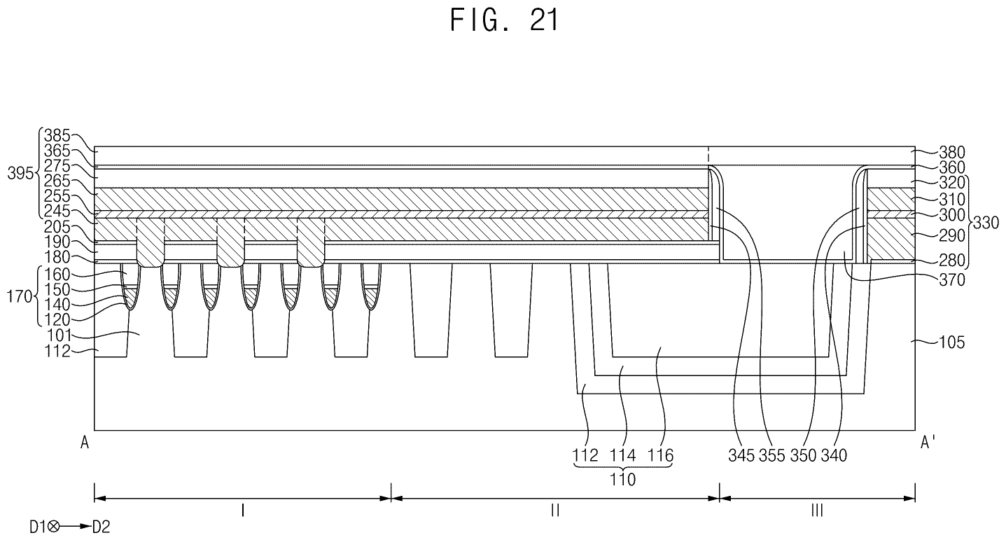

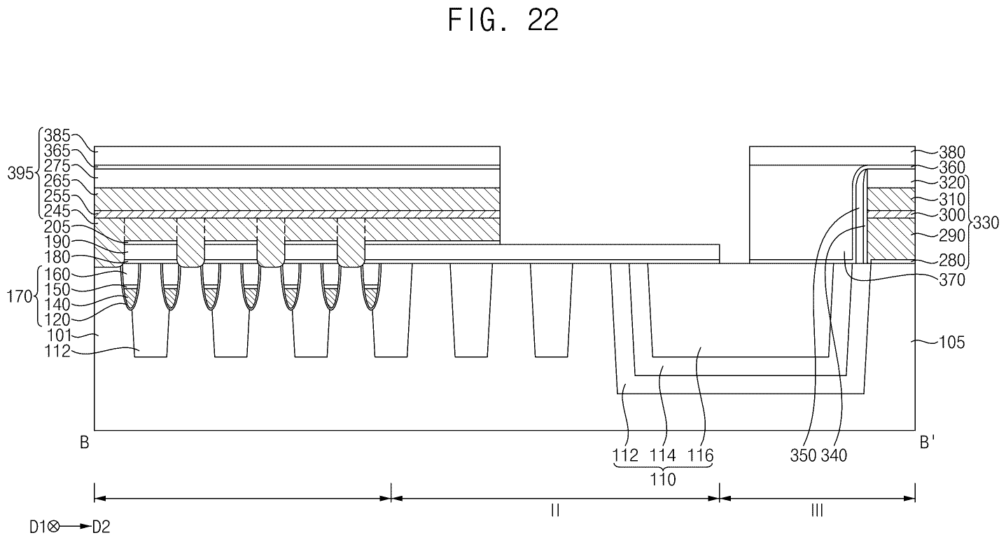

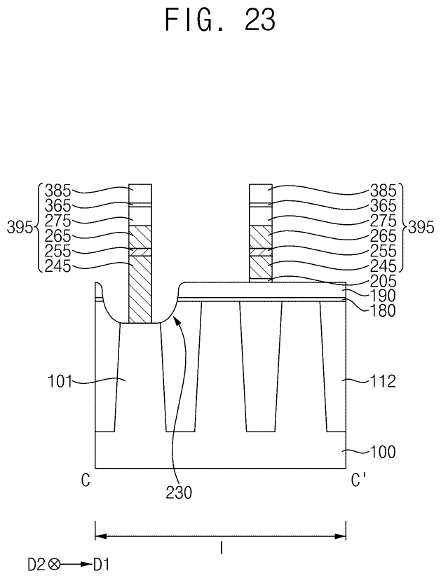

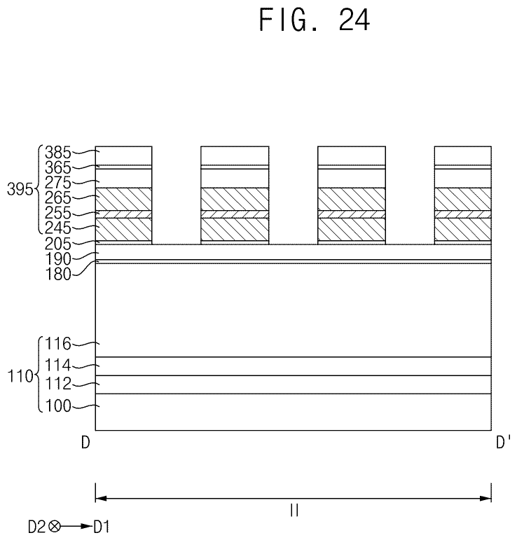

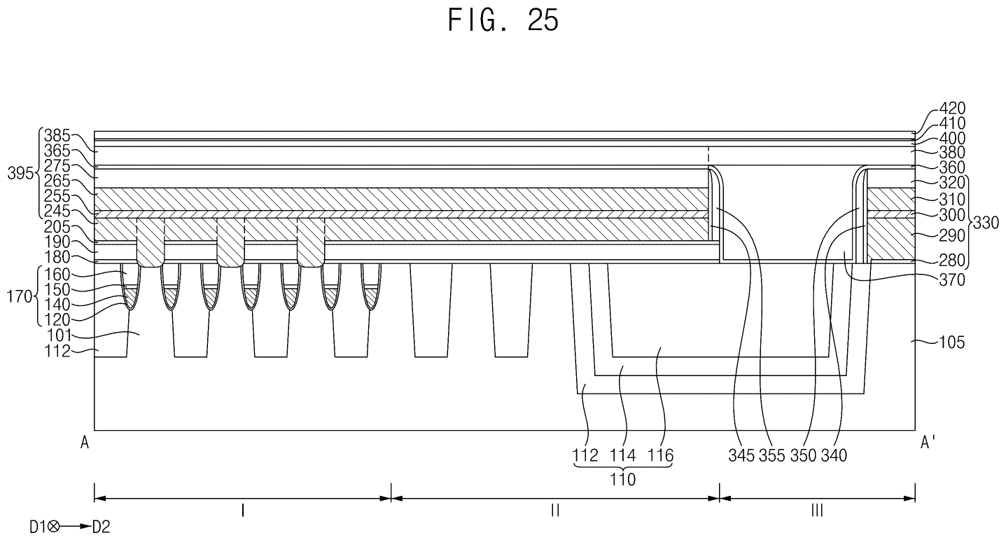

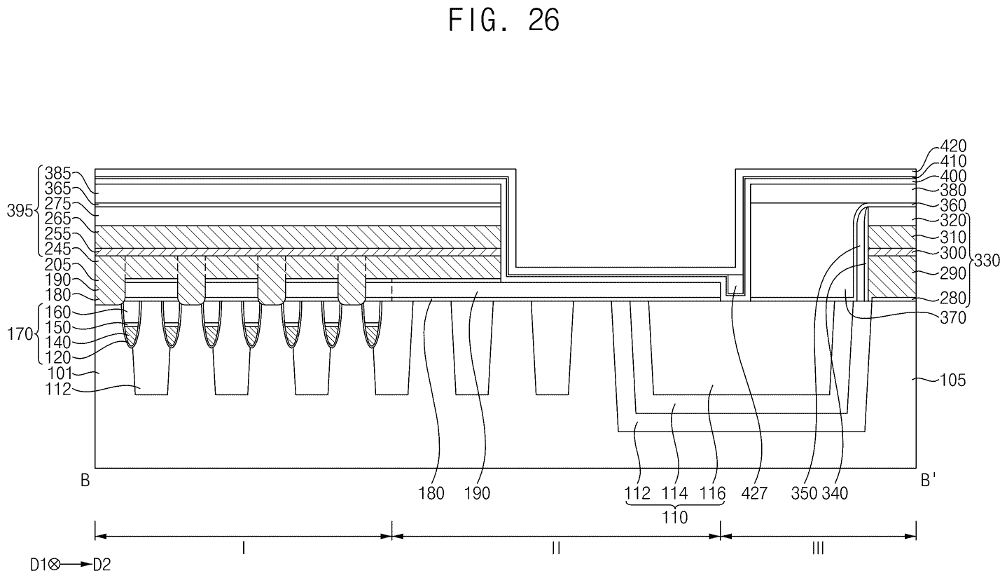

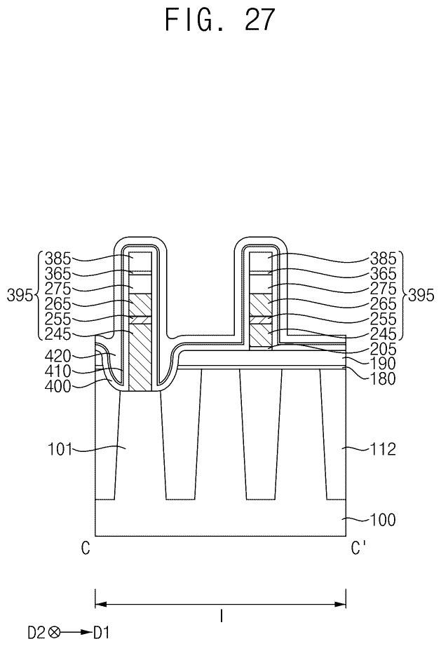

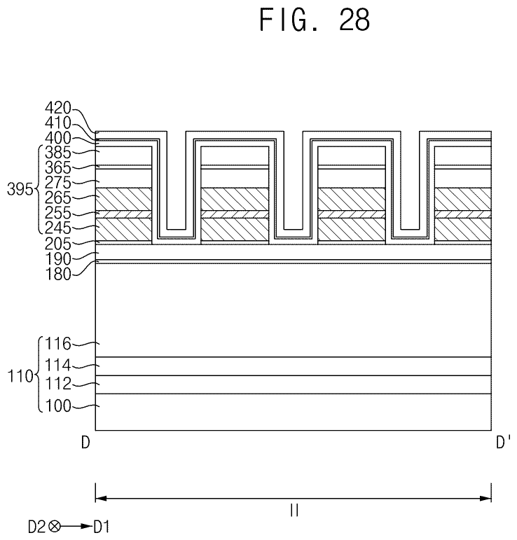

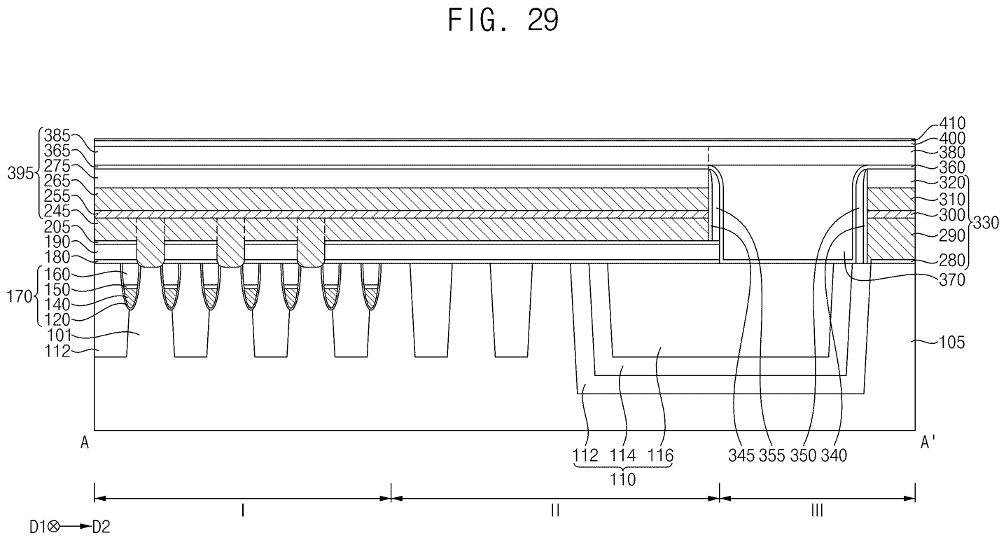

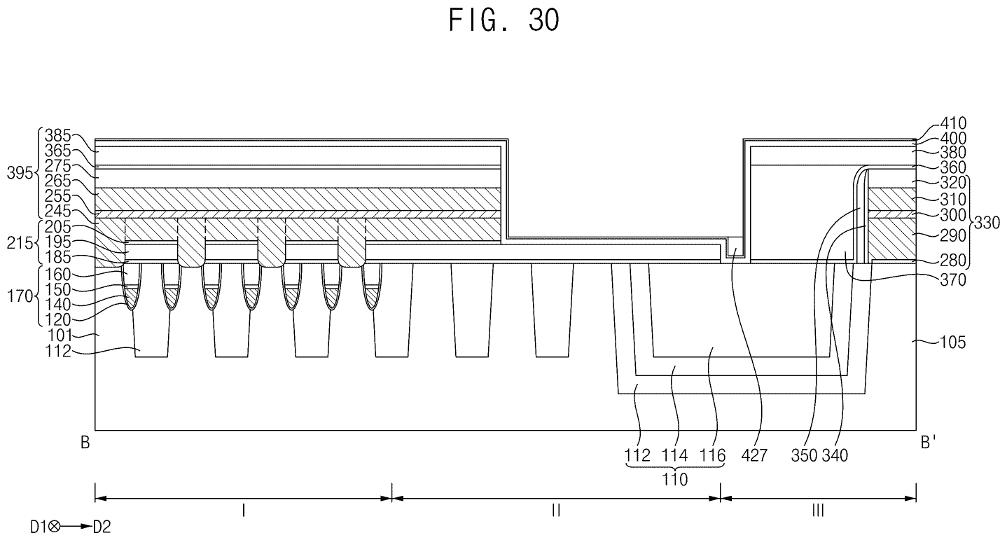

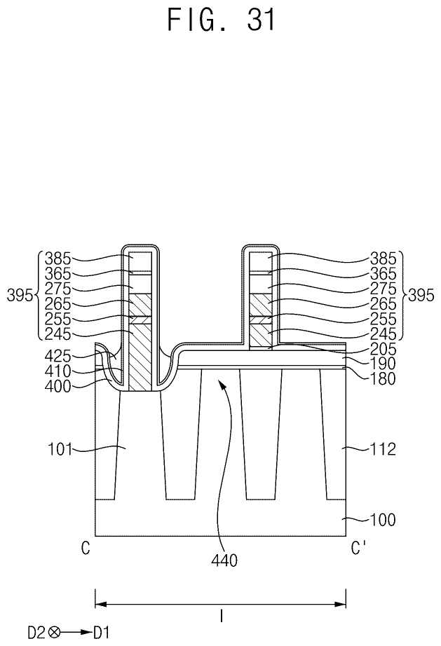

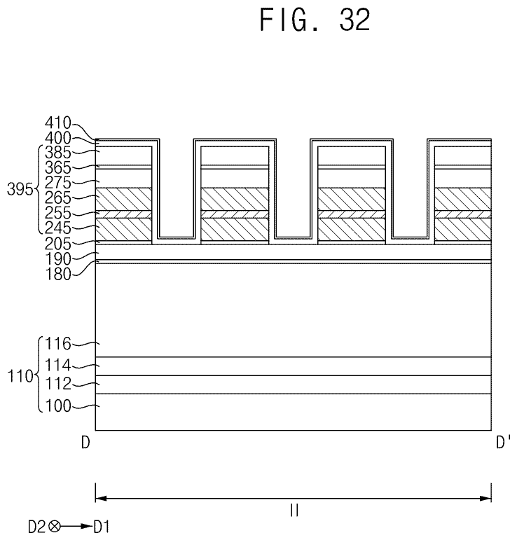

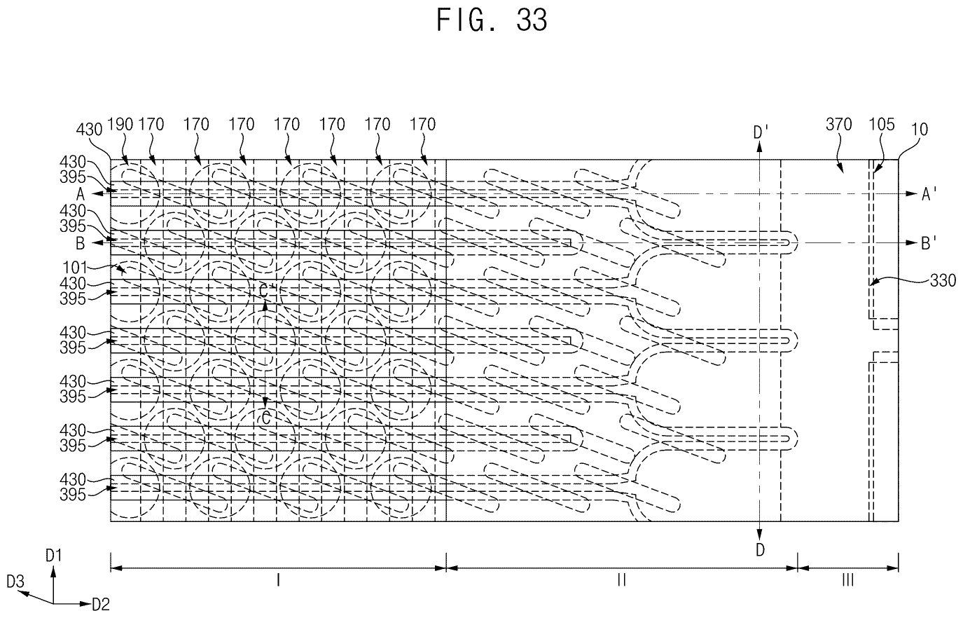

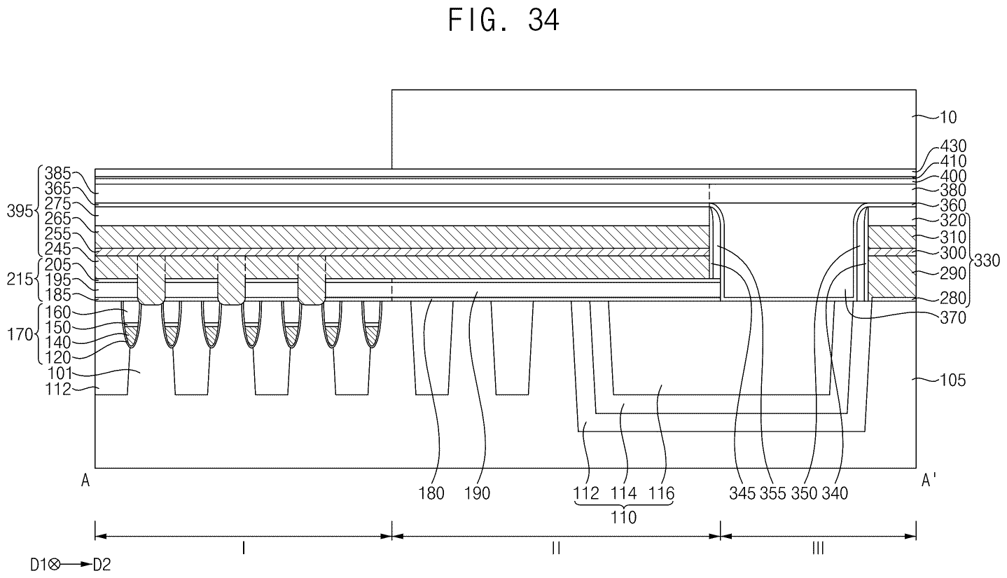

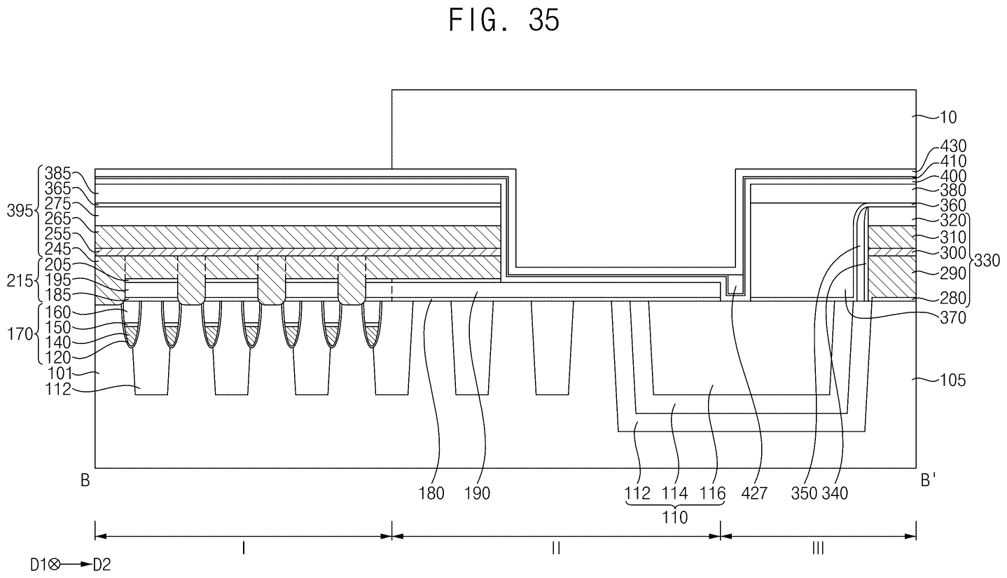

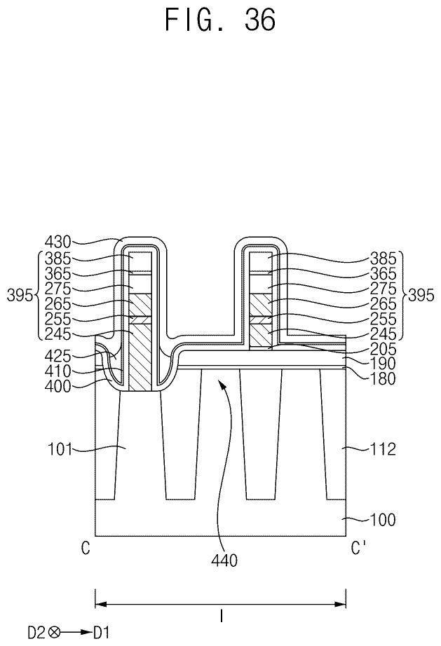

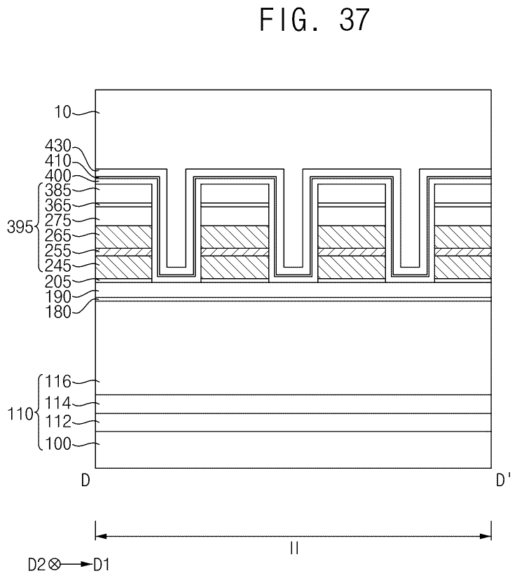

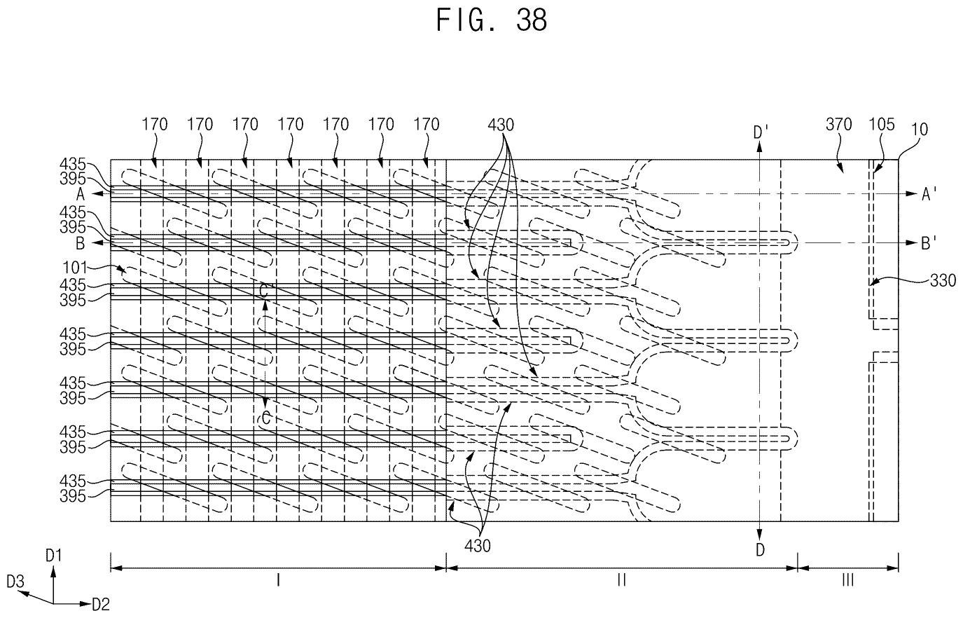

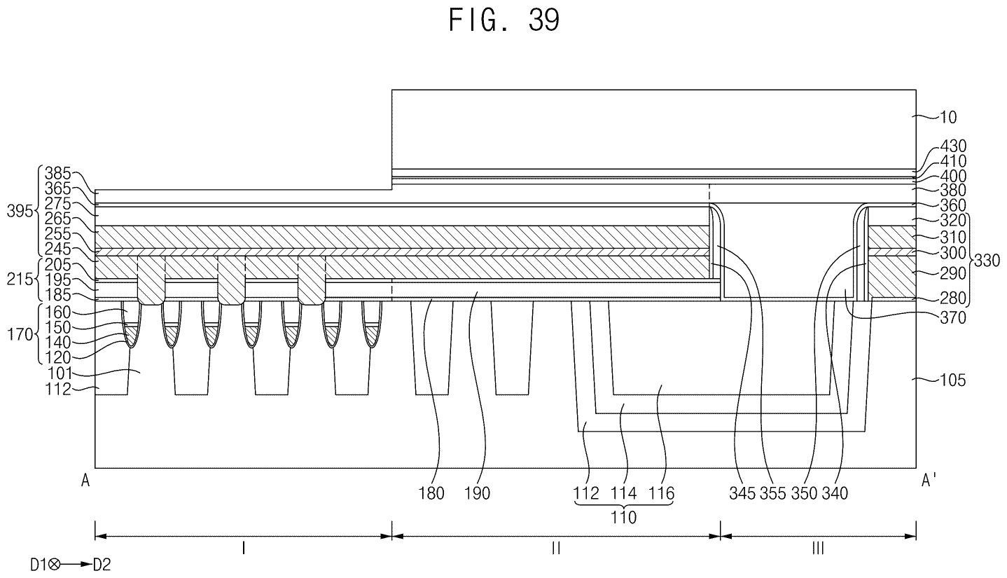

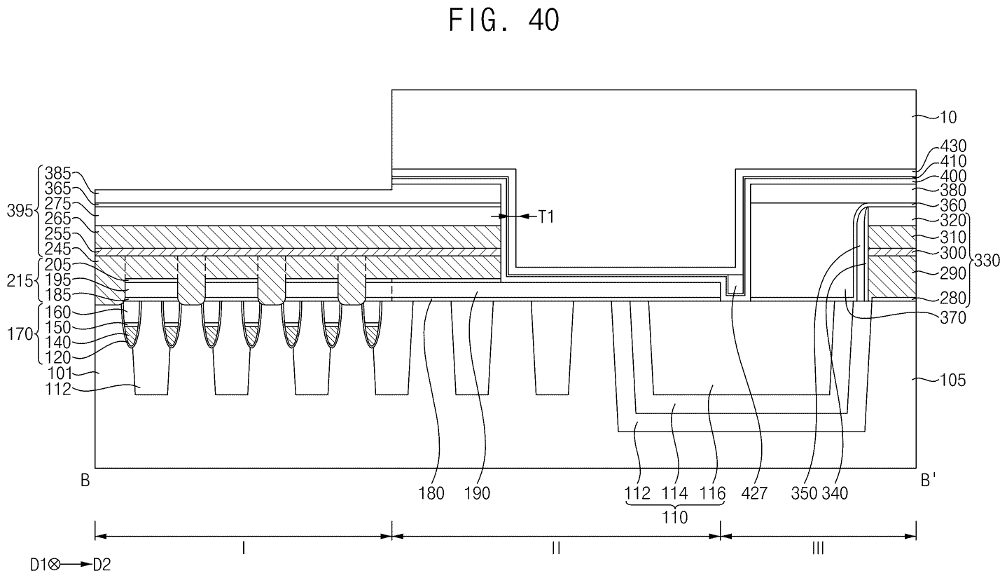

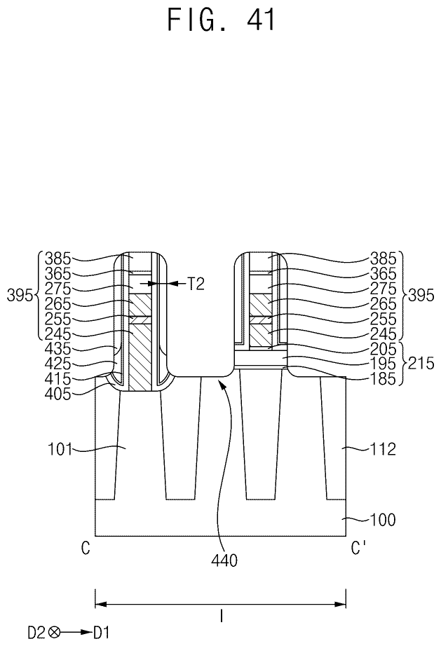

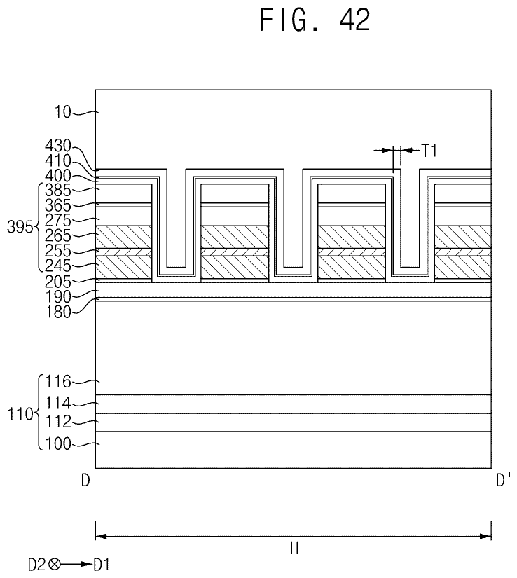

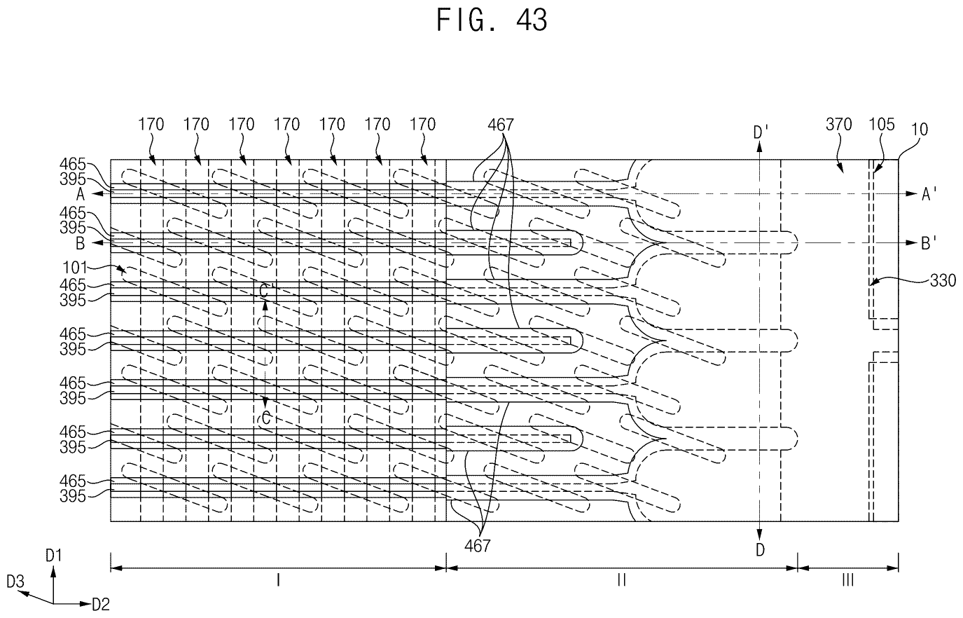

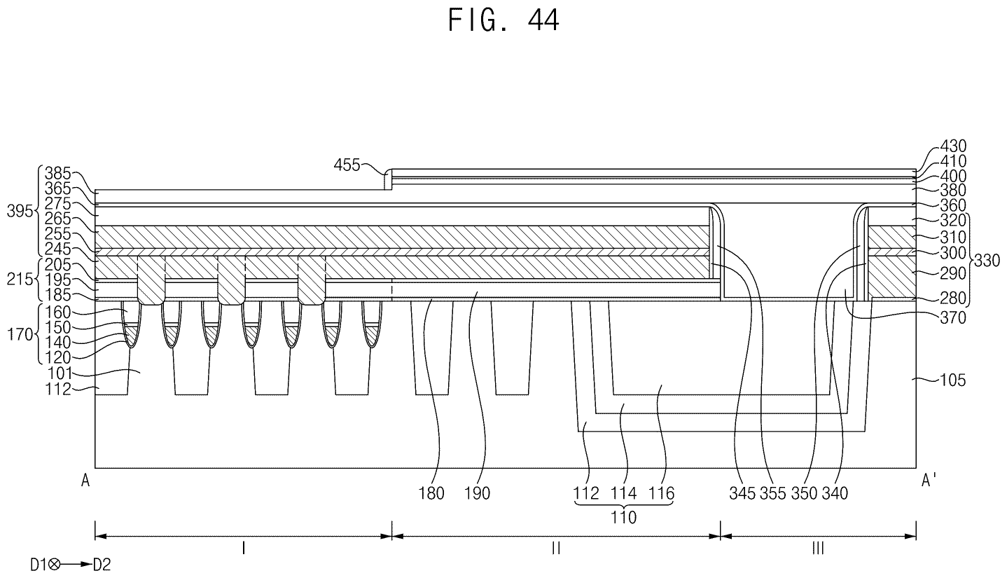

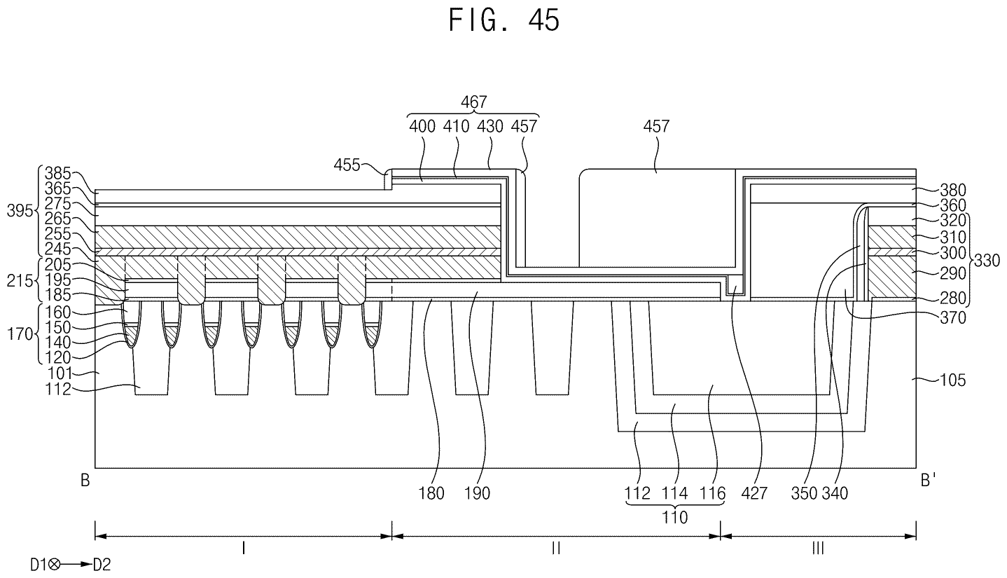

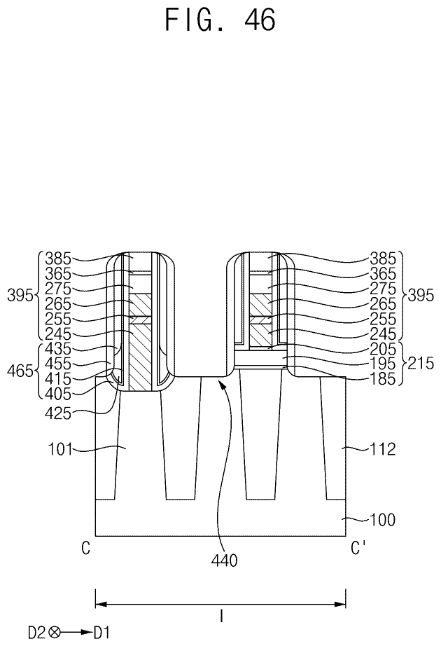

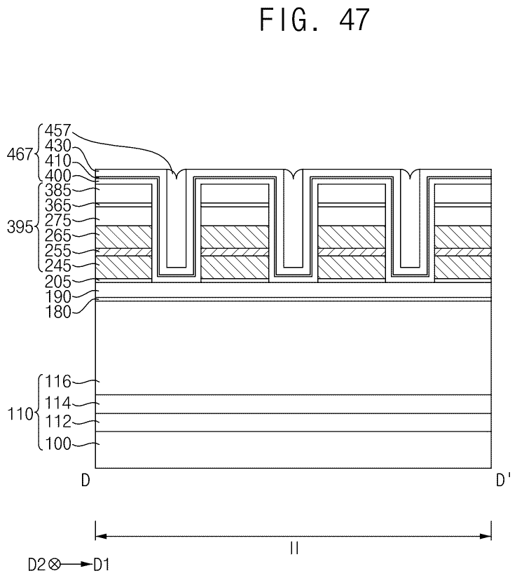

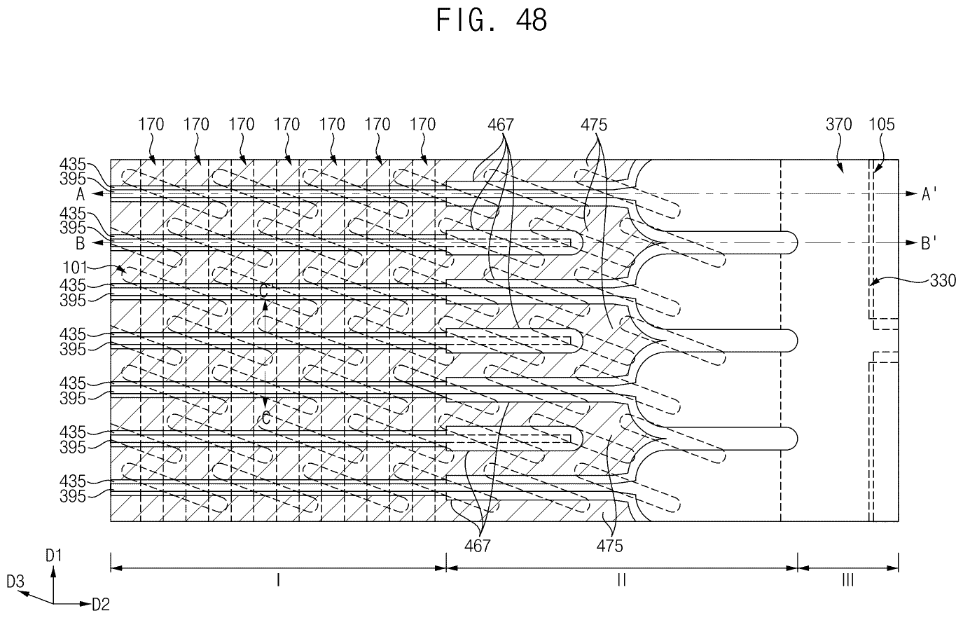

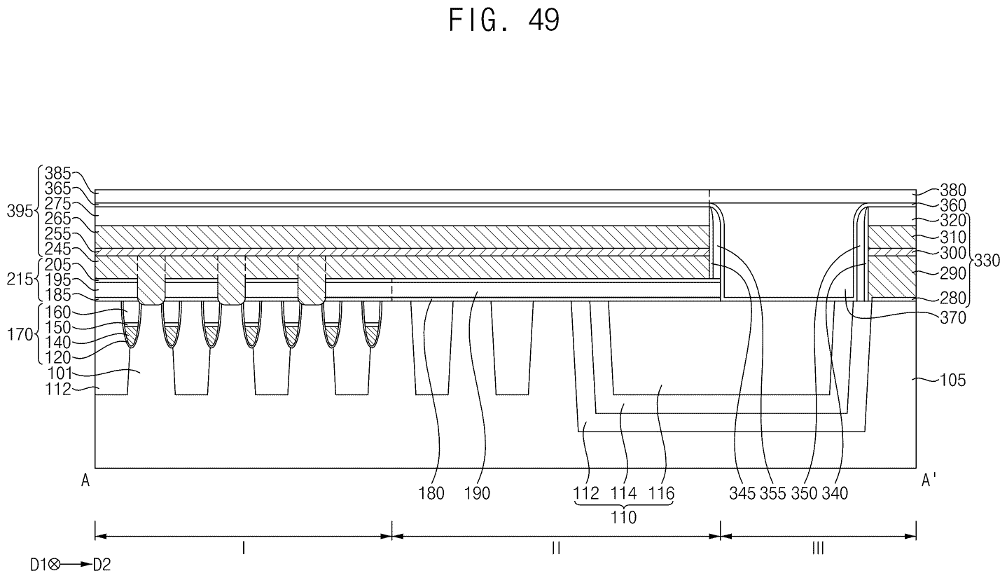

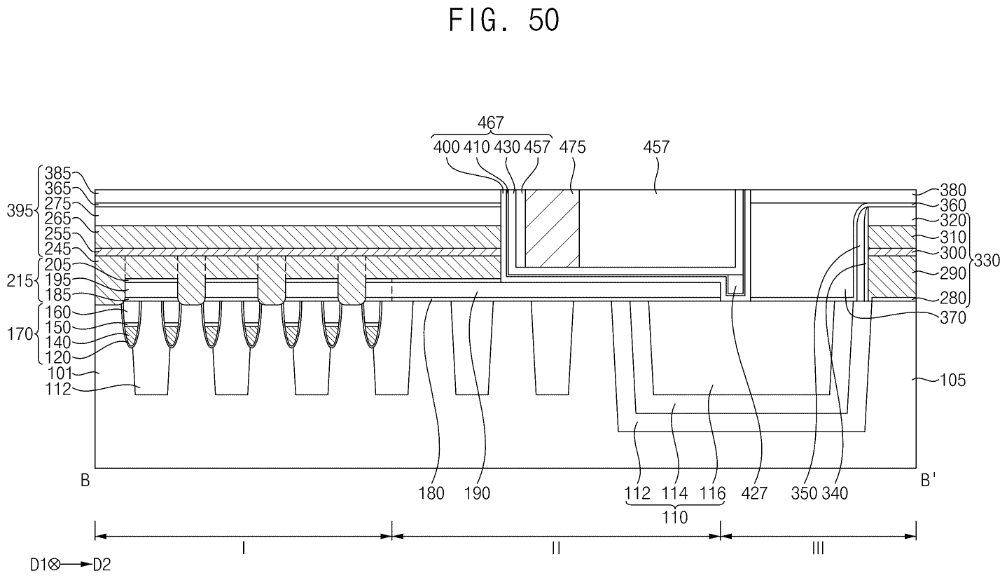

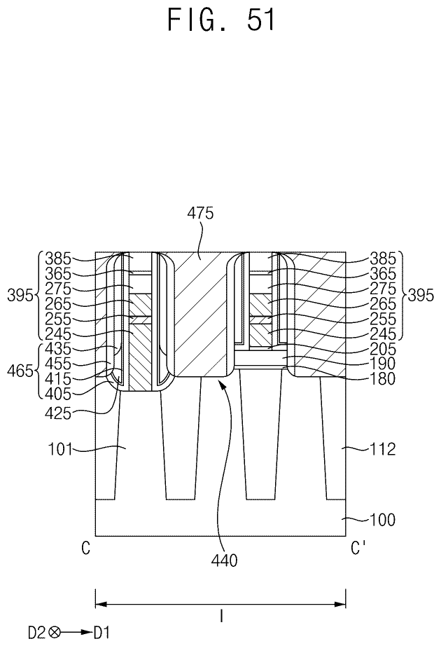

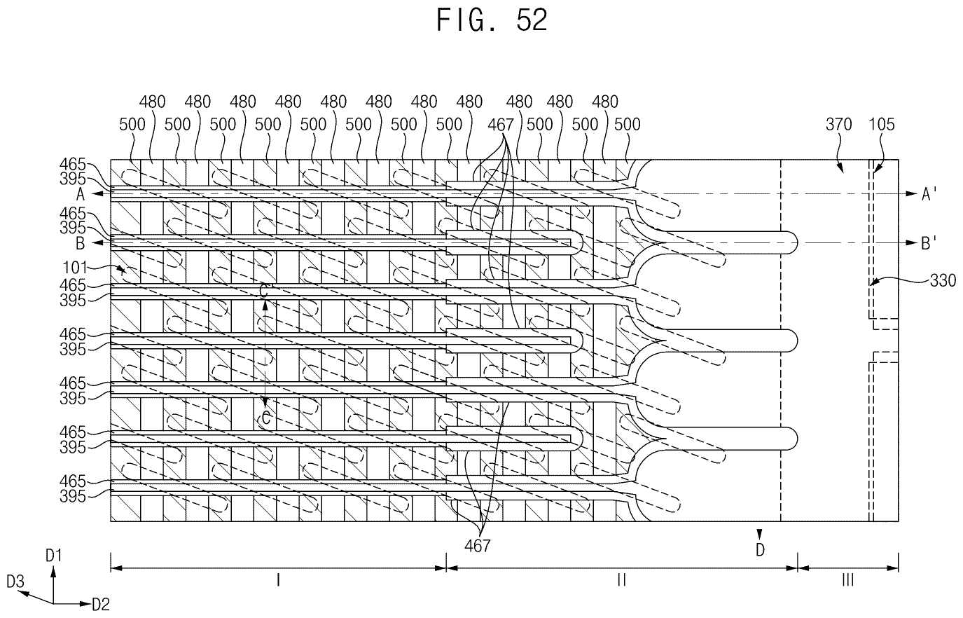

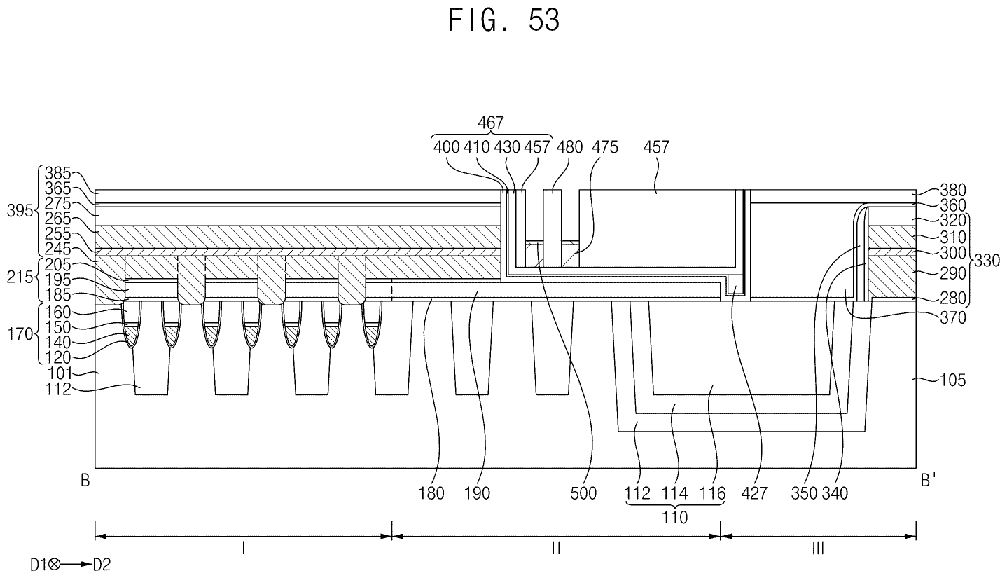

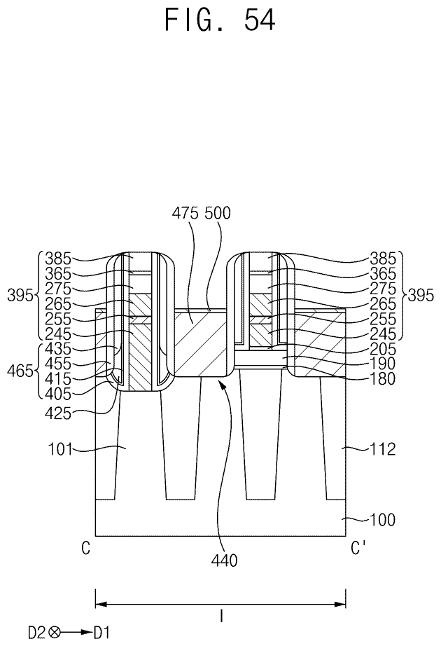

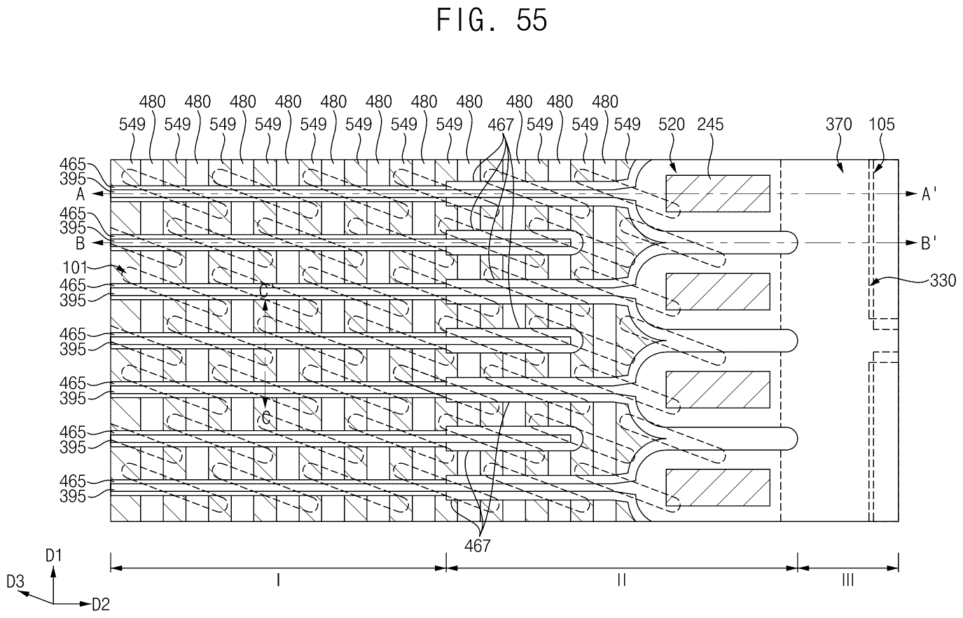

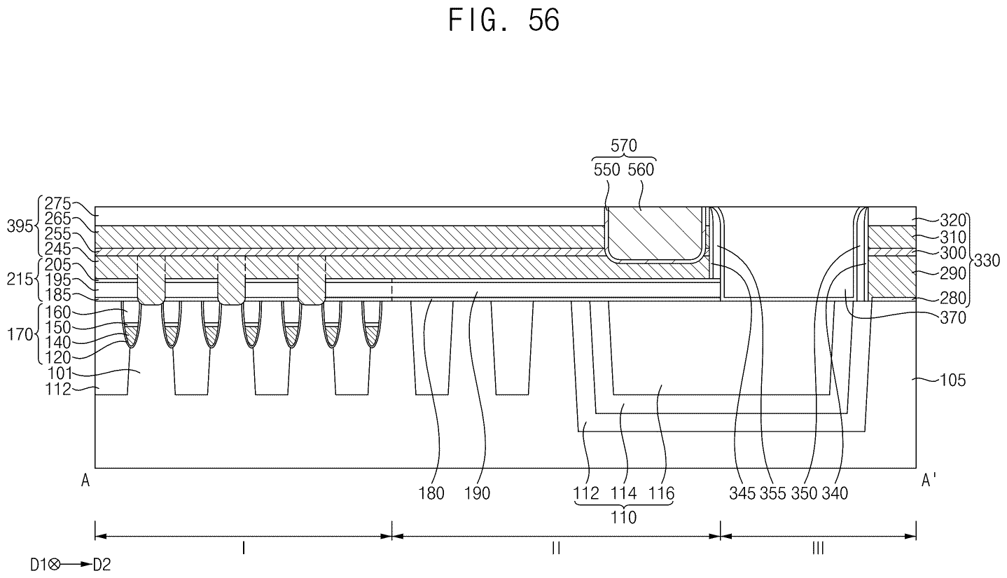

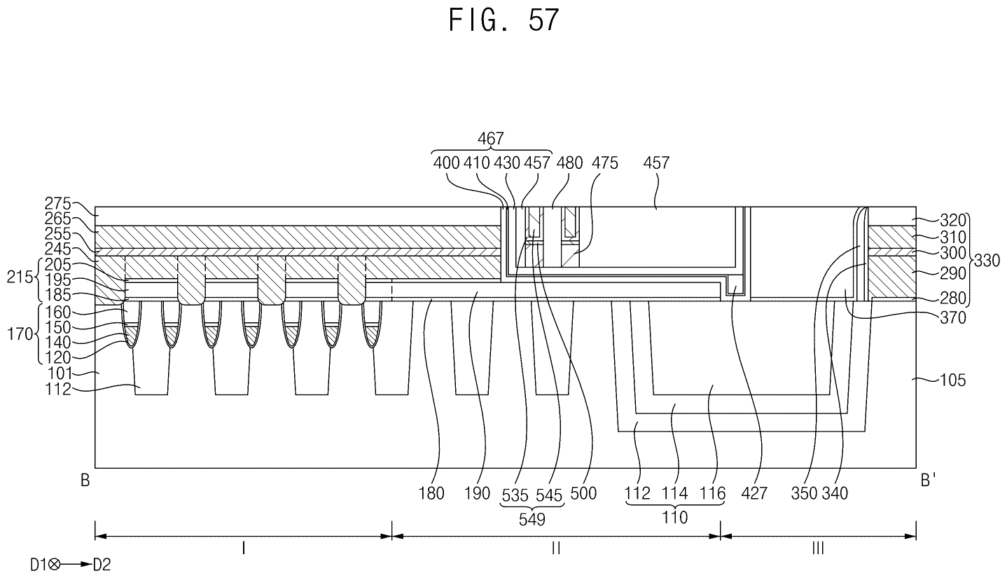

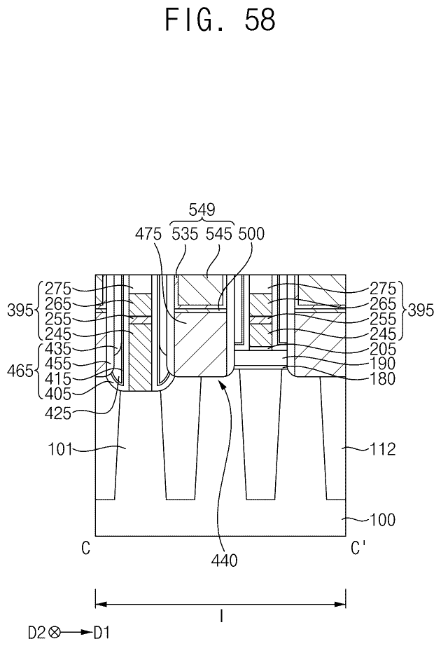

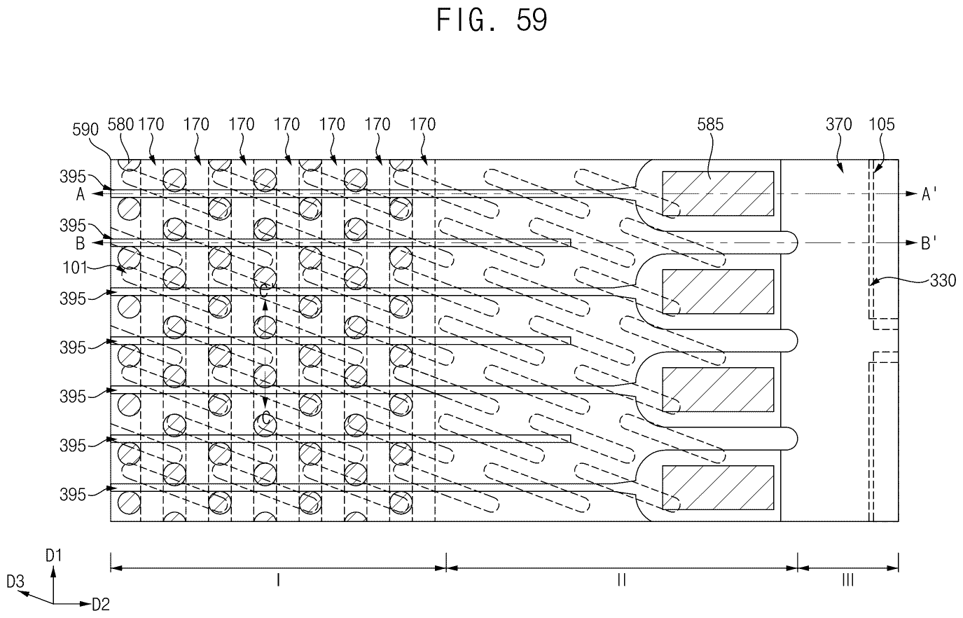

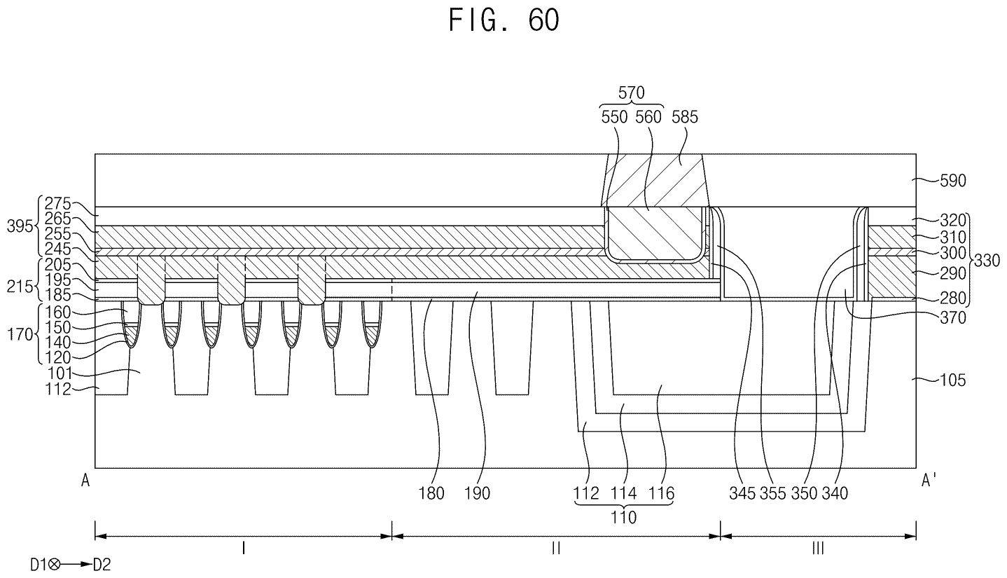

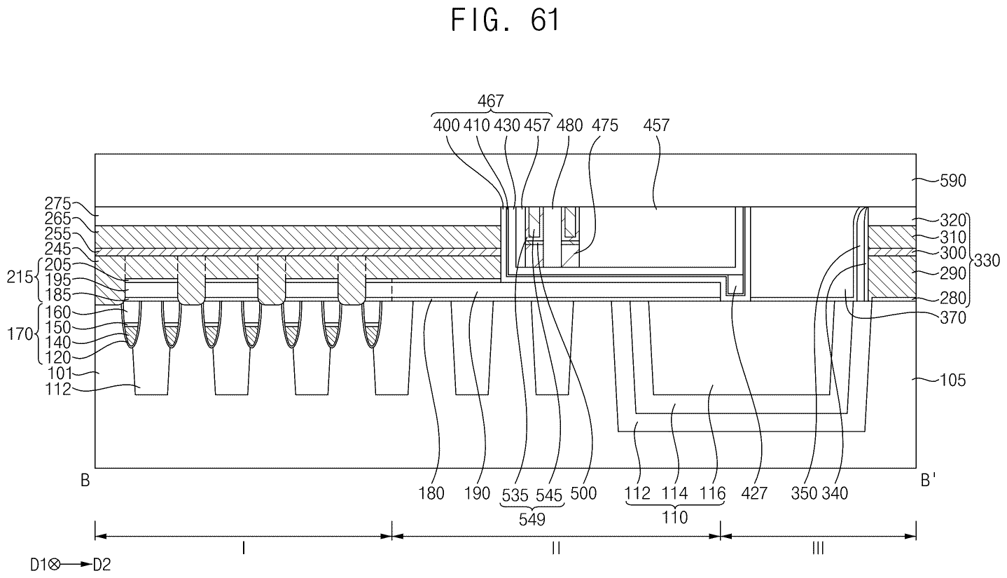

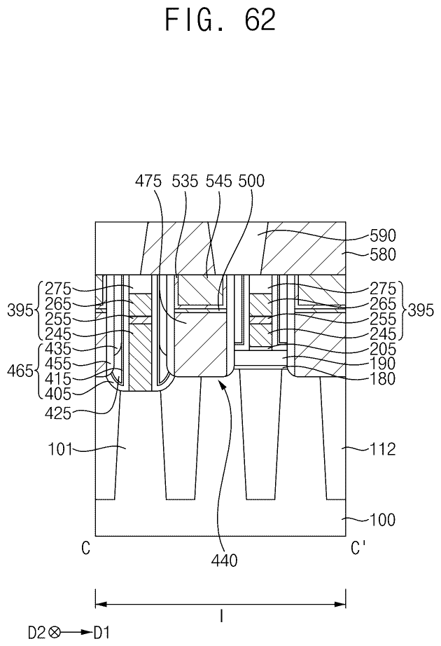

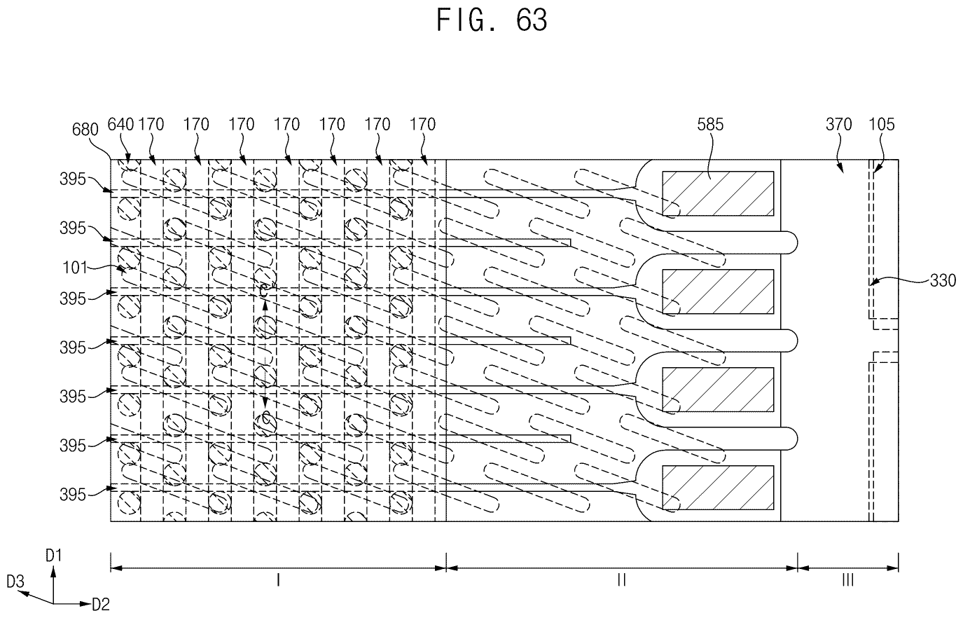

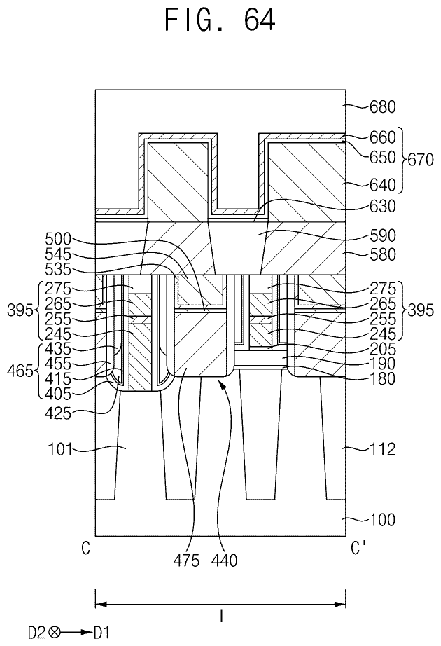

FIGS. 1 to 64 are plan views and cross-sectional views illustrating a method of manufacturing a semiconductor device according to various example embodiments.

Specifically, FIGS. 1-2, 5, 8, 15, 20, 33, 38, 43, 48, 52, 55, 59 and 63 are the plan views, FIGS. 3, 6, 9, 12, 16, 18, 21, 25, 29, 34, 39, 44, 49, 56 and 60 are cross-sectional views taken along lines A-A′ of corresponding plan views, respectively, FIGS. 10, 13, 17, 19, 22, 26, 30, 35, 40, 45, 50, 53, 57 and 61 are cross-sectional views taken along lines B-B′ of corresponding plan views, respectively, FIGS. 11, 14, 23, 27, 31, 36, 41, 46, 51, 54, 58, 62 and 64 are cross-sectional views taken along lines C-C′ of corresponding plan views, respectively, and FIGS. 24, 28, 32, 37, 42 and 47 are cross-sectional views taken along lines D-D′ of corresponding plan views, respectively.

Hereinafter, in the specification (and not necessarily in the claims), two directions substantially parallel to an upper surface of a substrate 100 and substantially perpendicular to each other may be referred to as first and second directions D1 and D2, respectively, and a direction substantially parallel to the upper surface of the substrate 100 and having an acute angle with respect to the first direction D1 and having an obtuse angle with the second direction D2 may be referred to as a third direction D3. A direction substantially the same as or similar to perpendicular to the upper surface of the substrate 100 may be referred to as a vertical direction. Each of the first to third directions D1, D2 and D3 may represent not only a direction shown in the drawing, but also a reverse direction to the direction.

Referring to FIGS. 1 to 4, first and second active patterns 101 and 105 may be formed on the substrate 100 including first to third regions I, II and III.

The substrate 100 may include silicon, germanium, silicon-germanium, or a III-V group compound semiconductor, such as GaP, GaAs, or GaSb. However, example embodiments are not limited thereto. In various example embodiments, the substrate 100 may be a silicon-on-insulator (SOI) substrate or a germanium-on-insulator (GOI) substrate.

The first region I of the substrate 100 may be a cell array region on which memory cells are formed, and the second region II of the substrate 100 may be an extension region on which upper contact plugs that transmit electrical signals to memory cells are formed. The first and second regions I and II may collectively form a cell region. The third region III of the substrate 100 surrounding the first and second regions I and II of the substrate 100 may be a peripheral circuit region on which peripheral circuit patterns for driving the memory cells are formed. In various example embodiments, the second region II of the substrate 100 may surround the first region I of the substrate 100, or may be formed at opposite sides in the second direction D2 of the first region I of the substrate 100. In various example embodiments, the third region III of the substrate 100 may surround the first and second region I and II of the substrate 100.

The first and second active patterns 101 and 105 may be formed by removing an upper portion of the substrate 100 to form a recess structure. The first active pattern 101 may extend in the third direction D3 on the first and second region I and II of the substrate 100, and a plurality of first active patterns 101 may be spaced apart from each other in each of the first and second directions D1 and D2 on the first and second region I and II of the substrate 100. Some of the first active patterns 101 on the second region II of the substrate 100 may be dummy active patterns. Additionally, a plurality of second active patterns 105 may be spaced apart from each other in each of the first and second directions D1 and D2 on the third region III of the substrate 100.

The recess structure may include first, second and third recesses 102, 104 and 106. The first recess 102 may be formed between ones of the first active patterns 101 spaced apart from each other by a relatively small distance on the first and second regions I and II of the substrate 100, the second recess 104 may be formed between ones of the first active patterns 101 spaced apart from each other by a relatively large distance on the first and second regions I and II of the substrate 100, and the third recess 106 may be formed on the third region III of the substrate 100 or between the second and third regions II and III of the substrate 100.

In various example embodiments, the third recess 106 may have a width and/or a depth greater than a width and/or a depth of the second recess 104, and the second recess 104 may have a width and/or a depth greater than a width and/or a depth of the first recess 102.

An isolation structure 110 may be formed to cover sidewalls of the first and second active patterns 101 and 105.

In various example embodiments, the isolation structure 110 may include first, second and third isolation patterns 112, 114 and 116 sequentially stacked on an inner wall of the third recess 106. However, the first and second isolation patterns 112 and 114 may be formed in the second recess 104 having a width smaller than that of the third recess 106, and the first isolation pattern 112 may be formed in the first recess 102 having a width smaller than that of the second recess 104.

Each of the first and third isolation patterns 112 and 116 may include an oxide, e.g., silicon oxide, and the second isolation pattern 114 may include an insulating nitride, e.g., silicon nitride.

Referring to FIGS. 5 to 7, an etching process may be performed on the first active pattern 101 and the isolation structure 110 on the first region I of the substrate 100 to form a fourth recess 40.

In various example embodiments, during the etching process, the first active pattern 101 including a semiconductor material may be less etched than the isolation structure 110 including an insulating material due to the etching selectivity. Thus, the fourth recess 40 may have a concave upper surface on an upper surface of the first active pattern 101.

A first gate insulation layer and a first conductive layer may be sequentially stacked on an inner wall of the fourth recess 40 and upper surfaces of the first and second active patterns 101 and 105 and the isolation structure 110, the first gate insulation layer and the first conductive layer may be planarized until the upper surfaces of the first and second active patterns 101 and 105 and the isolation structure 110 are exposed, and an upper portion of the first conductive layer may be removed by, e.g., an etch back process. The planarization process may include a chemical mechanical polishing (CMP) process and/or an etch back process.

By the planarization process, a first gate insulation pattern 120 may be formed on the inner wall of the fourth recess 40, and by the etch back process, a first conductive pattern 140 may be formed on the first gate insulation pattern 120 to fill a lower portion of the fourth recess 40.

A second conductive pattern 150 may be formed on the first conductive pattern 140, a first gate mask layer may be formed on the second conductive pattern 150, the first and second active patterns 101 and 105 and the isolation structure 110 to fill the fourth recess 40, and the first gate mask layer may be planarized until the upper surfaces of the first and second active patterns 101 and 105 and the isolation structure 110 are exposed, so that a first gate mask 160 may be formed to fill an upper portion of the fourth recess 40. The first conductive pattern 140 and the second conductive pattern 150 may collectively form a gate electrode, and a first barrier pattern may be further formed between the first gate insulation pattern 120 and the first conductive pattern 140.

The first gate insulation pattern 120 may include an oxide, e.g., silicon oxide, the first barrier pattern may include a metal nitride, e.g., titanium nitride, tantalum nitride, etc., the first conductive pattern 140 may include a metal, a metal nitride, a metal silicide, doped polysilicon, etc., the second conductive pattern 150 may include doped polysilicon, and the first gate mask 160 may include a nitride, e.g., silicon nitride. However, example embodiments are not limited thereto.

The first gate insulation pattern 120, the first barrier pattern, the first conductive pattern 140, the second conductive pattern 150 and the first gate mask 160 in the fourth recess 40 may collectively form a first gate structure 170. In various example embodiments, the first gate structure 170 may extend in the first direction D1 on the first region I of the substrate 100, and a plurality of first gate structures 170 may be spaced apart from each other in the second direction D2.

Referring to FIGS. 8 to 11, an insulation layer structure 210 may be formed on the first to third regions I, II and III of the substrate 100, and a portion of the insulation layer structure 210 on the third region III of the substrate 100 may be removed.

For example, a thermal oxidation process may be performed on the second active pattern 105 on the third region III of the substrate 100 to form a second gate insulation layer 220.

The insulation layer structure 210 may be patterned, and the first active pattern 101, the isolation structure 110, and the first gate mask 160 of the first gate structure 170 may be partially etched using the patterned insulation layer structure 210 as an etching mask to form a first opening 230.

In various example embodiments, the patterned insulation layer structure 210 may have a shape of a circle or an ellipse in a plan view, and a plurality of insulation layer structures 210 may be spaced apart from each other in the first and second directions D1 and D2 on the first region I of the substrate 100. Each of the insulation layer structures 210 may overlap in the vertical direction opposite end portions in the third direction D3 of adjacent ones of the first active patterns 101. In various example embodiments, the insulation layer structure 210 remaining on the second region II of the substrate 100 may have a shape of a rectangle in a plan view.

Referring to FIGS. 12 to 14, a third conductive layer 240, a second barrier layer 250, a fourth conductive layer 260 and a second mask layer 270 may be sequentially stacked on the insulation layer structure 210, the upper surfaces of the first active pattern 101, the isolation structure 110 and the first gate structure 170 exposed by the first opening 230 on the first and second regions I and II of the substrate 100, and the second gate insulation layer 220 and the isolation structure 110 on the third region III of the substrate 100, which may collectively form a conductive structure layer. The third conductive layer 240 may fill the first opening 230.

The third conductive layer 240 may include doped polysilicon, the second barrier layer 250 may include a metal silicon nitride, e.g., titanium silicon nitride, the fourth conductive layer 260 may include a metal, e.g., tungsten, and the second mask layer 270 may include a nitride, e.g., silicon nitride. However, example embodiments are not limited thereto.

Referring to FIGS. 15 to 17, the conductive structure layer may be patterned to form a second gate structure 330 on the third region III of the substrate 100.

The second gate structure 330 may include a second gate insulation pattern 280, a third conductive pattern 290, a second barrier pattern 300, a fourth conductive pattern 310 and a second gate mask 320 sequentially stacked in the vertical direction substantially perpendicular to an upper surface of the substrate 100, and the third conductive pattern 290, the second barrier pattern 300 and the fourth conductive pattern 310 may collectively form a second gate electrode.

The second gate structure 330 may at least partially overlap the second active pattern 105 in the vertical direction on the third region III of the substrate 100.

A portion of the conductive structure layer on an edge portion of the second region II of the substrate 100 adjacent to the third region III of the substrate 100 may also be removed, and thus the insulation layer structure 210, and the upper surfaces of the first active pattern 101, the isolation structure 110 and the first gate structure 170 exposed by the first opening 230 may also be partially exposed.

A first spacer structure may be formed on a sidewall of the second gate structure 330, and a second spacer structure may be formed on a sidewall of the conductive structure layer remaining on the first and second regions I and II of the substrate 100. The first spacer structure may include first and third spacers 340 and 350 stacked on the sidewall of the second gate structure 330 in a horizontal direction substantially parallel to the upper surface of the substrate 100, and the second spacer structure may include second and fourth spacers 345 and 355 stacked on the sidewall of the conductive structure layer in the horizontal direction.

The first and second spacers 340 and 345 may be formed by forming a first spacer layer on the substrate 100 to cover the conductive structure layer and the second gate structure 330 and anisotropically etching the first spacer layer. The third and fourth spacers 350 and 355 may be formed by forming a second spacer layer on the substrate 100 to cover the conductive structure layer, the second gate structure 330 and the first and second spacers 340 and 345 and anisotropically etching the second spacer layer.

The first and second spacers 340 and 345 may include a nitride, e.g., silicon nitride, and the third and fourth spacers 350 and 355 may include an oxide, e.g., silicon oxide.

However, the structure of the first and second spacer structures may not be limited thereto, and each of the first and second spacer structures may include a single spacer or more than two spacers sequentially stacked.

A first etch stop layer 360 may be formed on the substrate 100 to cover the conductive structure layer, the second gate structure 330, the first and second spacer structures, and the isolation structure 110. The first etch stop layer 360 may include an insulating nitride, e.g., silicon nitride.

Referring to FIGS. 18 and 19, a first insulating interlayer 370 may be formed on the first etch stop layer 360 to a sufficient height, the first insulating interlayer 370 may be planarized until an upper surface of the second gate structure 330 and an upper surface of a portion of the first etch stop layer 360 on the conductive structure layer are exposed, and a capping layer 380 may be formed on the first insulating interlayer 370 and the first etch stop layer 360.

Thus, the first insulating interlayer 370 may fill a space between the first spacer structures on the sidewall of the second gate structures 330, and a space between the first spacer structure on the sidewall of the second gate structure 330 and the second spacer structure on the sidewall of the conductive structure layer.

The first insulating interlayer 370 may include an oxide, e.g., silicon oxide, and the capping layer 380 may include a nitride, e.g., silicon nitride. However, example embodiments are not limited thereto.

Referring to FIGS. 20 to 24, a portion of the capping layer 380 on the first and second regions I and II of the substrate 100 may be etched to form a capping pattern 385, and the first etch stop layer 360, the second mask layer 270, the fourth conductive layer 260, the second barrier layer 250 and the third conductive layer 240 may be sequentially etched using the capping pattern 385 as an etching mask.

In various example embodiments, the capping pattern 385 may extend in the second direction D2 on the first and second regions I and II of the substrate 100, and a plurality of capping patterns 385 may be formed to be spaced apart from each other in the first direction D1. The capping layer 380 may remain on the third region III of the substrate 100 and a portion the second region II of the substrate 100 adjacent thereto.

By the etching process, on the first and second regions I and II of the substrate 100, a fifth conductive pattern 245, a third barrier pattern 255, a sixth conductive pattern 265, a second mask 275, a first etch stop pattern 365 and the capping pattern 385 may be sequentially stacked on the first opening 230, and a third insulation pattern 205, the fifth conductive pattern 245, the third barrier pattern 255, the sixth conductive pattern 265, the second mask 275, the first etch stop pattern 365 and the capping pattern 385 may be sequentially stacked on the second insulation layer 190 of the insulation layer structure 210 at an outside of the first opening 230.

Hereinafter, the fifth conductive pattern 245, the third barrier pattern 255, the sixth conductive pattern 265, the second mask 275, the first etch stop pattern 365 and the capping pattern 385 sequentially stacked may be referred to as a bit line structure 395.

In various example embodiments, the bit line structure 395 may extend in the second direction D2 on the first and second regions I and II of the substrate 100, and a plurality of bit line structures 395 may be spaced apart from each other in the first direction D1.

A first bit line structure of the bit line structures 295 may be formed to include a first extension portion and a first pad portion. The first extension portion may be formed to extend in the second direction D2 on the first region I of the substrate 100 and the second region II of the substrate 100 adjacent thereto, and the first pad portion may be formed to extend in the second direction D2 from a right end of the first extension portion in the second direction D2 on the second region II of the substrate 100 adjacent to the third region III of the substrate 100. A width in the first direction D1 of the first pad portion may be greater than a width in the first direction D1 of the first extension portion.

A second bit line structure of the bit line structures 295 may be formed to include a second extension portion and a second pad portion. The second extension portion may be formed to extend in the second direction D2 on the first region I of the substrate 100 and the second region II of the substrate 100 adjacent thereto, and second first pad portion may be formed to extend in the second direction D2 from a left end of the first extension portion in the second direction D2 on the second region II of the substrate 100 adjacent to the third region III of the substrate 100. A width in the first direction D1 of the second pad portion may be greater than a width in the first direction D1 of the second extension portion.

In various example embodiments, the first and second bit line structures may be alternately and repeatedly formed in the first direction D1.

In the drawings, a portion of the second region II of the substrate 100 on which the first pad portions of the first bit line structures are formed, and the first and third regions I and III of the substrate 100 adjacent thereto in the second direction D2 are illustrated.

In various example embodiments, the first pad portions of the first bit line structures may be aligned with each other in the first direction D1, and right ends of the second extension portions in the second direction D2 of the second bit line structures may be aligned with each other in the first direction D1. The right end of the first extension portion in the second direction D2 of the first bit line structure may be closer to the third region III of the substrate 100 than the right end of the second extension portion in the second direction D2 of the second bit line structure. That is, on the portion of the second region II of the substrate 100 on which the first pad portion of the first bit line structure is formed, the first bit line structure may extend longer in the second direction D2 than the second bit line structure.

Similarly, the second pad portions of the second bit line structures may be aligned with each other in the first direction D1, and left ends of the first extension portions in the second direction D2 of the first bit line structures may be aligned with each other in the first direction D1. The left end of the second extension portion in the second direction D2 of the second bit line structure may be closer to the third region III of the substrate 100 than the left end of the first extension portion in the second direction D2 of the first bit line structure. That is, on a portion of the second region II of the substrate 100 on which the second pad portion of the second bit line structure is formed, the second bit line structure may extend longer in the second direction D2 than the first bit line structure.

The second gate structure 330, the first and second spacer structures, a portion of the insulation layer structure 210, and the isolation structure 110 may remain on the third region III of the substrate 100 and a portion of the second region II of the substrate 100 adjacent thereto. Additionally, the capping layer 380 may remain on portions of the first etch stop layer 360 on an upper surface of the second gate structure 330 and the first insulating interlayer 370.

Referring to FIGS. 25 and 28, fifth and sixth spacer layers 400 and 410 may be sequentially formed on the bit line structure 395 and the capping layer 380 on the substrate 100, and a fourth insulation layer 420 may be formed on the sixth spacer layer 410.

The fifth spacer layer 400 may also cover a sidewall of the third insulation pattern 205 between the second insulation layer 190 and the bit line structure 395, and the fourth insulation layer 420 may fill the first opening 230.

The fifth spacer layer 400 may include an insulating nitride, e.g., silicon nitride, the sixth spacer layer 410 may include an oxide, e.g., silicon oxide, or a carbonate, e.g., silicon carbonate, and the fourth insulation layer 420 may include an insulating nitride, e.g., silicon nitride. However, example embodiments are not limited thereto.

Referring to FIGS. 29 to 32, the fourth insulation layer 420 may be etched by an etching process.

In various example embodiments, the etching process may be performed by a wet etch process using an etching solution including phosphorous acid (H₃PO₄), and other portions of the fourth insulation layer 420 except for a portion in the first opening 230 may be removed. Thus, most of an entire surface of the sixth spacer layer 410, that is, an entire surface except for a portion thereof in the first opening 230 may be exposed, and portions of the fourth insulation layer 420 remaining in the first opening 230 may form a fourth insulation pattern 425.

In various example embodiments, the fourth insulation layer 420 may remain between the first pad portions of the first bit line structures adjacent to each other in the first direction D1 on the second and third regions II and III of the substrate 100. The portion of the fourth insulation layer 420 remaining between the first pad portions of the first bit line structures may be referred to as a fifth insulation pattern 427.

Referring to FIGS. 33 to 37, a seventh spacer layer 430 may be formed on the exposed surface of the sixth spacer layer 410, the fourth insulation patterns 425 in the first opening 230, and the fifth insulation pattern 427.

The seventh spacer layer 430 may include an oxide, e.g., silicon oxide. In various example embodiments, the seventh spacer layer 430 and a portion of the sixth spacer layer 410 that may contact the seventh spacer layer 430 may be merged with each other and may not be distinguished from each other.

A photoresist structure 10 may be formed on the second and third regions II and III of the substrate 100. Accordingly, a portion of the seventh spacer layer 430 on the second and third regions II and III of the substrate 100, excluding a portion of the seventh spacer layer 430 on the first region I of the substrate 100, may be covered.

In various example embodiments, the photoresist structure 10 may include a mold layer, an anti-reflection layer and a photoresist pattern sequentially stacked on the second and third regions II and III of the substrate 100. The mold layer may include, but is not limited to, e.g., a Spin-On-Hardmask (SOH), an amorphous carbon layer (ACL), etc., the anti-reflection layer may include, e.g., silicon oxynitride, and the photoresist pattern may include, e.g., a photoresist material whose chemical properties may change in response to light.

Referring to FIGS. 38 to 42, the seventh spacer layer 430 may be anisotropically etched.

Accordingly, a seventh spacer layer 430 may be formed on the surface of the sixth spacer layer 410 and an upper surface of the fourth insulation pattern 425 to cover a sidewall of the extension portion of the bit line structure 395.

A dry etching process may be performed to form a second opening 440 exposing the upper surface of the first active pattern 101. An upper surface of the isolation structure 110 and an upper surface of the first gate mask 160 may also be exposed by the second opening 440.

By the dry etching process, portions of the fifth and sixth spacer layers 400 and 410 on the capping patterns 385 and the second insulation layer 190 may be removed, and thus, fifth and sixth spacers 405 and 415 sequentially stacked on the sidewall of the bit line structure 395 may be formed. The fifth spacer 405 may cover the sidewall of the bit line structure 395.

Additionally, during the dry etching process, the first and second insulation layers 180 and 190 may be partially removed, such that first and second insulation patterns 185 and 195 may remain under the bit line structure 395. The first to third insulation patterns 185, 195 and 205 that are sequentially stacked under the bit line structure 395 may collectively form an insulation pattern structure 215.

The portion of the seventh spacer layer 430 on the fourth insulation layer 420 on the second and third regions II and III of the substrate 100 may be covered by the photoresist structure 10, and thus, may not be exposed during the anisotropic etching process. Accordingly, a first thickness T1 of the seventh spacer layer 430 may be greater than a second thickness T2 of the seventh spacer 435 exposed to the anisotropic etching process.

Likewise, portions of the first and second insulation layers 180 and 190 and the fifth and sixth spacer layers 400 and 410 below the seventh spacer layer 430 on the second and third regions II and III of the substrate 100 may be covered by the photoresist structure 10 so as to remain without being exposed to the anisotropic etching process. That is, on the second region II of the substrate 100, the first and second insulation layers 180 and 190 and the fifth to seventh spacer layers 400, 410 and 430 may be sequentially stacked in the vertical direction on the upper surfaces of the first active pattern 101 and the isolation structure 110.

Referring to FIGS. 43 to 47, the photoresist structure 10 may be removed, thereby exposing the seventh spacer layer 430 on the second and third regions II and III of the substrate 100.

In various example embodiments, the photoresist structure 10 may be removed by performing, e.g., an ashing process.

Thereafter, an eighth spacer layer may be formed on an upper surface of the capping pattern 385, portions of upper surfaces of the fifth and sixth spacers 405 and 415, an outer sidewall of the seventh spacer 435, a portion of an upper surface of the fourth insulation pattern 425, and the upper surfaces of the first active pattern 101, the isolation structure 110 and the first gate mask 160 exposed by the second opening 440 on the first region I of the substrate 100, and an upper surface of the fifth insulation pattern 427 and a surface of the seventh spacer layer 430 on the second and third regions II and III of the substrate 100.

Thereafter, the eighth spacer layer may be anisotropically etched. Accordingly, an eighth spacer 455 covering an outer sidewall of seventh spacer 435 on the sidewall in the first direction D1 of the bit line structure 395 on the first region I of the substrate 100, and a ninth spacer 457 covering an outer sidewall of the seventh spacer layer 430 on the sidewall of the bit line structure 395 on the second region II of the substrate 100 may be formed. Each of the eighth and ninth spacers 455 and 457 may include an insulating nitride, e.g., silicon nitride.

In various example embodiments, on the second region II of the substrate 100, a width in the first direction D1 between the first pad portions of the first bit line structures adjacent to each other in the first direction D1 may be smaller than a width in the first direction D1 between the first extension portion of the first bit line structure and the second extension portion of the second bit line structure adjacent to each other in the first direction D1. Accordingly, the ninth spacers 457 at opposite sidewalls of the first pad portions of the first bit line structures adjacent to each other in the first direction D1 may be merged with each other. That is, the ninth spacer 457 may be formed to fill a space between the first pad portions of the first bit line structures adjacent to each other in the first direction D1.

The fifth to eighth spacers 405, 415, 435 and 455 sequentially stacked in the horizontal direction from the sidewall of the bit line structure 395 on the first region I of the substrate 100 may be referred to as a third spacer structure 465, and the fifth to seventh spacer layers 400, 410 and 430 and the ninth spacer 457 sequentially stacked in the horizontal direction from the sidewall of the bit line structure 395 on the second region II of the substrate 100 may be referred to as a fourth spacer structure 467.

As illustrated above, the first thickness T1 of the seventh spacer layer 430 on the sidewall of the bit line structure 395 at the second region II of the substrate 100 may be greater than the second thickness T2 of the seventh spacer 435 on the sidewall of the bit line structure 395 at the first region I of the substrate 100. Accordingly, a third thickness in the horizontal direction of the fourth spacer structure 467 on the sidewall of the bit line structure 395 at the second region II of the substrate 100 may be greater than a fourth thickness in the horizontal direction of the third spacer structure 465 on the sidewall of the bit line structure 395 at the first region I of the substrate 100.

Referring to FIGS. 48 to 51, a lower contact plug layer may be formed on the first and second regions I and II of the substrate 100 to fill the second opening 440, and upper portions of the lower contact plug layer, the capping layer 380, the capping pattern 385 and the third and fourth spacer structures 465 and 467 may be planarized until the upper surface of the capping pattern 385 is exposed to form a first contact plug 475.

The first contact plug 475 may extend in the second direction D2 on the first and second regions I and II of the substrate 100 between neighboring ones of the bit line structures 395 in the first direction D1, and a plurality of first contact plugs 475 may be spaced apart from each other in the first direction D1. Each of the first contact plugs 475 may contact an upper surface of an end portion in the third direction D3 of the first active pattern 101 extending in the third direction D3 on the first region I of the substrate 100.

In comparison, on the second region II of the substrate 100, each of the first contact plugs 475 may overlap in the vertical direction with the end portion in the third direction D3 of the first active pattern 101, but may not make contact due to the first and second insulation layers 180 and 190 and the firth to seventh spacer layers 400, 410 and 430. Accordingly, the first active patterns 101 on the second region II of the substrate 100 may be dummy active patterns as illustrated above.

In various example embodiments, the first contact plugs 475 extending in the second direction D2 along sidewalls in the first direction D1 of the second bit line structure may meet at a right end of the second bit line structure in the second direction D2 and merge with each other.

In various example embodiments, the ninth spacer 457 may fill the space between the first pad portions of the first bit line structures adjacent to each other in the first direction D1, and thus, the first contact plug 475 may not be formed between the first pad portions of the first bit line structures.

Referring to FIGS. 52 to 54, an etching mask having third openings, each of which may extend in the first direction D1, spaced apart from each other in the second direction D2 may be formed on the capping layer 380, the bit line structure 395 and the first contact plug 475, and an etching process may be performed on the first contact plug 475 using the etching mask to form a fourth opening 445.

In various example embodiments, on the first region I of the substrate 100, the third opening may overlap the first gate structure 170 in the vertical direction, and the fourth opening 445 may expose an upper surface of the first gate mask 160 of the first gate structure 170. On the second region II of the substrate 100, the third openings may be spaced apart from each other in the second direction D2 at a same interval as in the first region I of the substrate 100, and the fourth opening 445 may expose the upper surface of the seventh spacer layer 430 on the second region II of the substrate 100. As the fourth opening 445 is formed, the first contact plug 475 extending in the second direction D2 may be divided into a plurality of parts spaced apart from each other in the second direction D2.

After removing the etching mask, a fence pattern 480 may be formed to fill the fourth opening 445. A plurality of fence patterns 480 may be spaced apart from each other in the second direction D2 between the bit line structures 395 on the first and second regions I and II on the substrate 100. The fence pattern 480 may include an insulating nitride, e.g., silicon nitride.

As illustrated above, the third thickness of the fourth spacer structure 467 on the second region II of the substrate 100 may be greater than the fourth thickness of the third spacer structure 465 on the first region I of the substrate 100. Accordingly, a first width in the first direction D1 of the first contact plug 475 on the second region II of the substrate 100 may be smaller than a second width in the first direction D1 of the first contact plug 475 on the first region I of the substrate 100. Likewise, a third width in the first direction D1 of the fence pattern 480 on the second region II of the substrate 100 may be smaller than a fourth width in the first direction D1 of the fence pattern 480 on the first region I of the substrate 100.

In various example embodiments, a fifth width in the first direction D1 of the first contact plug 475 between the right end of the first extension portion in the second direction D2 of the first bit line structure and the right end of the second extension portion in the second direction D2 of the second bit line structure may be greater than the first width or the second width in the first direction D1 of the first contact plug 475 left to the right end of the second extension portion in the second direction D2 of the second bit line structure.

As illustrated above, the first contact plugs 475 and the fence patterns 480 may be alternately and repeatedly arranged in the second direction D2 may be formed by forming the lower contact plug layer extending in the second direction D2 between the bit line structures 395, planarizing the lower contact plug layer to form the first contact plug 475, forming the fourth openings 445 through the first contact plug 475 that are spaced apart from each other in the second direction D2, and filling the fourth opening 445 by the fence pattern 480, however, example embodiments are not limited thereto.

Alternatively, the first contact plugs 475 and the fence patterns 480 may be alternately and repeatedly arranged in the second direction D2 may be formed by forming a fence layer extending in the second direction D2 between the bit line structures 395, forming fifth openings through the fence layer spaced apart from each other in the second direction D2 to divide the fence layer into the fence patterns 480, forming the lower contact plug layer on the fence layer to fill the fifth openings, and planarizing the lower contact plug layer to form the first contact plugs 475.

Alternatively, the first contact plugs 475 and the fence patterns 480 may be alternately and repeatedly arranged in the second direction D2 may be formed by forming a sacrificial layer including an oxide, e.g., silicon oxide and extending in the second direction D2 between the bit line structures 395, forming the fence patterns 480 through the sacrificial layer spaced apart from each other in the second direction D2, removing the sacrificial layer to form sixth openings, forming the lower contact plug layer to fill the sixth openings, and planarizing the lower contact plug layer to form the first contact plugs 475.

Thereafter, an upper portion of the first contact plug 475 may be removed to expose an upper portion of the third and fourth spacer structures 465 and 467 on the sidewalls of the bit line structure 395.

An ohmic contact pattern 500 may be formed on the exposed upper surface of the first contact plug 475. In various example embodiments, the ohmic contact patterns 500 may be formed by forming a first metal layer on the capping pattern 385, the capping layer 380, the third and fourth spacer structures 465 and 467, the fence pattern 480, and the first contact plug 475, thermally treating the first metal layer, and removing an unreacted portion of the first metal layer. The ohmic contact patterns 500 may include a metal silicide, e.g., cobalt silicide, nickel silicide, titanium silicide, etc. However, example embodiments are not limited thereto.

Referring to FIGS. 55 and 58, a seventh opening 520 may be formed through a portion of the capping pattern 385 on the portion of the second region II of the substrate 100 adjacent to the third region III of the substrate 100, and the first etch stop layer 360, the second mask 275, the sixth conductive pattern 265 and the third barrier pattern 255 to expose the fifth conductive pattern 245.

In various example embodiments, a plurality of seventh opening 520 may be spaced apart from each other in the first direction D1 on the second region II of the substrate 100.

A fourth barrier layer may be formed on the capping pattern 385, the third spacer structure 465, the fence pattern 480 and the ohmic contact pattern 500 on the first region I of the substrate 100, and the capping layer 380, the capping pattern 385, the fourth spacer structure 467, a sidewall of the seventh opening 520, and the fifth conductive pattern 245, the third barrier pattern 255, the sixth conductive pattern 265 and the second mask 275 exposed by the seventh opening 520 on the second and third region II and III of the substrate 100. A second metal layer 540 may be formed on the fourth barrier layer to fill a space between the bit line structures 395, between the bit line structure 395 and the seventh opening 520.

Thereafter, a planarization process may be performed on the second metal layer, the fourth barrier layer, the capping pattern 385, the third spacer structure 465, the fence pattern 480 and the first etch stop pattern 365 on the first region I of the substrate 100, and the capping layer 380, the capping pattern 385, the fourth spacer structure 467, the fence pattern 480 and the first etch stop pattern 365 on the second and third regions II and III of the substrate 100, until an upper surface of the second mask 275 is exposed.

By the planarization process, the second metal layer and the fourth barrier layer may be respectively transformed to a first metal pattern 545 and a fourth barrier pattern 535 covering a lower surface of the first metal pattern 545 on the first region I of the substrate 100 and the second region II of the substrate 100 adjacent thereto. The first metal pattern 545 and the fourth barrier pattern 535 may collectively form the second contact plug 549. In various example embodiments, a plurality of second contact plugs 549 may be spaced apart from each other in the first and second directions D1 and D2 on the first region I of the substrate 100 and the second region II of the substrate 100 adjacent thereto, and may be arranged in a lattice pattern in a plan view.

The first contact plug 475, the ohmic contact pattern 500 and the second contact plug 549 on the first region I of the substrate 100 and the second region II of the substrate 100 adjacent thereto may collectively form a contact plug structure.

Corresponding to the first contact plug 475, a first width of the contact plug structure on the second region II of the substrate 100 may be smaller than a second width of the contact plug structure on the first region I of the substrate 100.

In various example embodiments, corresponding to the first contact plug 475, a fifth width in the first direction D1 of the contact plug structure between the right end of the first extension portion in the second direction D2 of the first bit line structure and the right end of the second extension portion in the second direction D2 of the second bit line structure may be greater than the first width or the second width in the first direction D1 of the contact plug structure left to the right end of the second extension portion in the second direction D2 of the second bit line structure.

By the planarization process, the second metal layer and the fourth barrier layer may be respectively transformed to a second metal pattern 560 and a fifth barrier pattern 550 covering a lower surface of the second metal pattern 560 within the seventh opening 520. The second metal pattern 560 and the fifth barrier pattern 550 may collectively form an upper contact plug 570. In various example embodiments, a plurality of upper contact plugs 570 may be spaced apart from each other in the first direction D1 on the second region II of the substrate 100 adjacent to the third region III of the substrate 100. The upper contact plug 570 may contact the fifth conductive pattern 245, the third barrier pattern 255 and the sixth conductive pattern 265, and accordingly, may apply electrical signals to the bit line structure 395.

Referring to FIGS. 59 to 62, a fifth conductive layer may be formed on the capping pattern 385, the third spacer structure 465, the fence pattern 480 and the contact plug structure on the first region I of the substrate 100, and the capping layer 380, the capping pattern 385, the fourth spacer structure 467, the fence pattern 480, the contact plug structure and the upper contact plug 570 on the second and third regions II and III of the substrate 100. The fifth conductive layer may include a metal, e.g., tungsten, or a metal nitride, e.g., titanium nitride. However, example embodiments are not limited thereto.

Thereafter, the fifth conductive layer may be patterned, and a third contact plug 580 and an upper wiring 585 may be formed. The third contact plug 580 may be formed on and be electrically connected to the contact plug structure, and the upper wiring 585 may be formed on and be electrically connected to the upper contact plug 570.

In various example embodiments, a plurality of third contact plugs 580 may be spaced apart from each other in the first and second directions D1 and D2 on the first region I of the substrate 100, and may be arranged in a honeycomb pattern in a plan view. The third contact plug 580 may have a shape of a circle, an ellipse, or a polygon in a plan view.

In various example embodiments, a plurality of upper wirings 585 may be spaced apart from each other in the first direction D1 on the second region II of the substrate 100.

A second insulating interlayer 590 may be formed to cover sidewalls of the third contact plug 580 and the upper wiring 585. The second insulating interlayer 590 may include an oxide, e.g., silicon oxide, or an insulating nitride, e.g., silicon nitride. However, example embodiments are not limited thereto.

Referring to FIGS. 63 and 64, a capacitor 665 may be formed to contact an upper surface of the third contact plug 580 on the first region I of the substrate 100.

Particularly, a second etch stop layer 630 and a mold layer may be sequentially formed on the third contact plug 580, the second insulating interlayer 590, and may be partially etched to form a ninth opening partially exposing an upper surface of the third contact plug 580. The second etch stop layer 630 may include an insulating nitride, e.g., silicon nitride. However, example embodiments are not limited thereto.

A lower electrode layer may be formed on the exposed upper surface of the third contact plug 580 and the mold layer to fill the ninth opening, and may be planarized until an upper surface of the mold layer is exposed to separate the lower electrode layer into nodes. Thereafter, the mold layer may be removed by, e.g., a wet etching process. Accordingly, a lower electrode 640 may be formed to have a pillar shape on the exposed upper surface of the third contact plug 580. Alternatively, the lower electrode 640 may be formed to have a cylindrical shape. The lower electrode may include, e.g., a metal, a metal nitride, a metal silicide, doped polysilicon, etc. However, example embodiments are not limited thereto.

A dielectric layer 650 and an upper electrode 660 may be sequentially formed on a surface of the lower electrode 640 and an upper surface of the second etch stop layer 630 to form the capacitor 670 including the lower electrode 640, the dielectric layer 650 and the upper electrode 660 on the first region I of the substrate 100.

The dielectric layer 650 may include, e.g., a metal oxide, and the upper electrode 660 may include, e.g., a metal, a metal nitride, a metal silicide, doped polysilicon, etc. However, example embodiments are not limited thereto.

Contact plugs and upper wirings may be further formed on the substrate 100 to be electrically connected to the first and second gate structures 170 and 330, the bit line structure 395, the capacitor 670, etc., so that the fabrication of the semiconductor device may be completed.

As illustrated above, the seventh spacer layer 430 may be formed on the bit line structure 395 on the first and second regions I and II of the substrate 100, the photoresist structure 10 may be formed to cover the seventh spacer layer 430 on the second and third regions II and III of the substrate 100, and the anisotropic etching process may be performed only on the exposed portion of the seventh spacer layer 430 on the first region I of the substrate 100 to form the seventh spacer 435.

The anisotropic etching process may not be performed on the portion of the seventh spacer layer 430 on the sidewall of the bit line structure 395 on the second region II of the substrate 100, and hence, may not be damaged. Accordingly, damage to the bit line structure 395 may be prevented or reduced by the intact seventh spacer layer 430, and thus, the semiconductor device may have improved electrical characteristics.

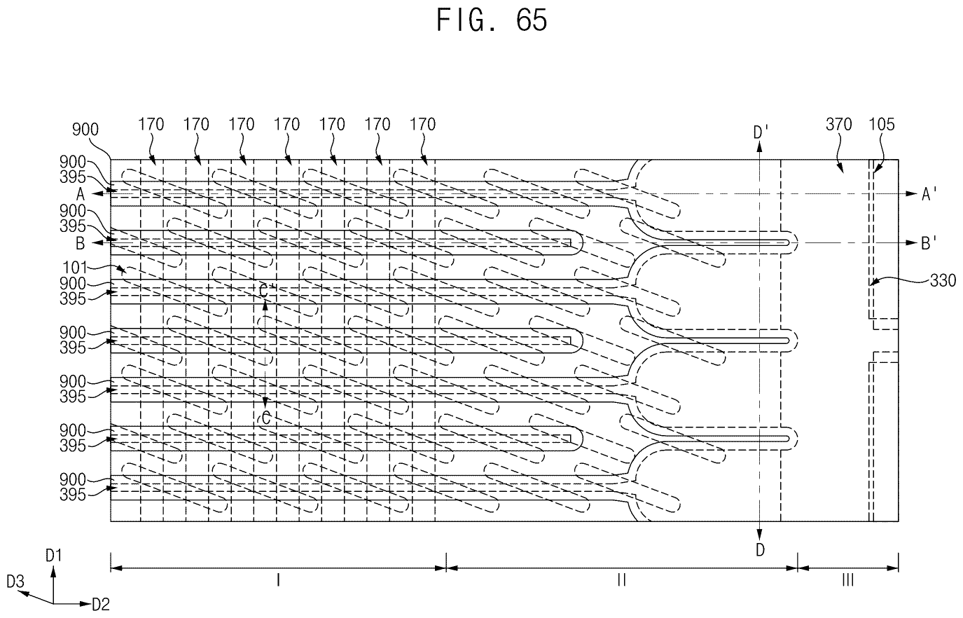

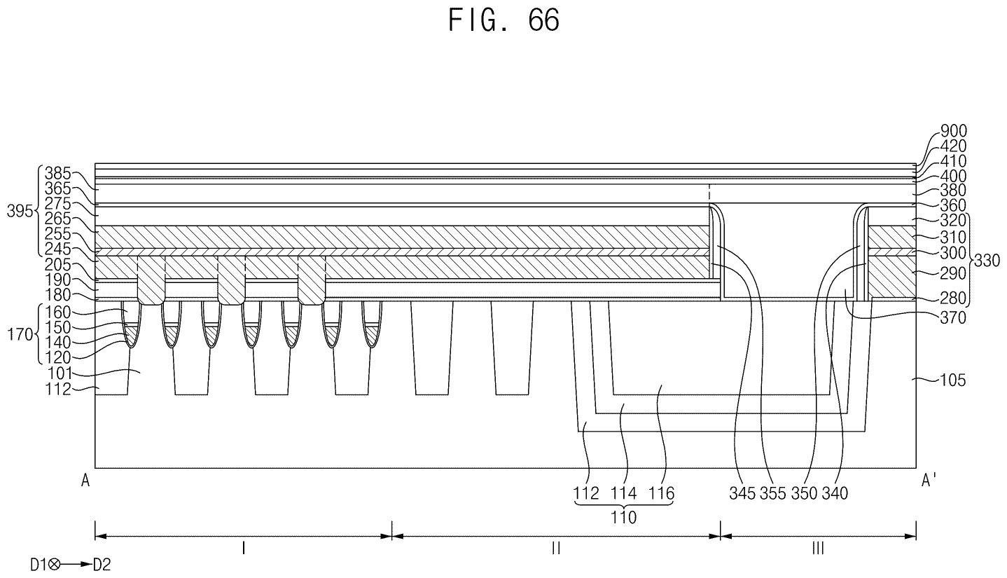

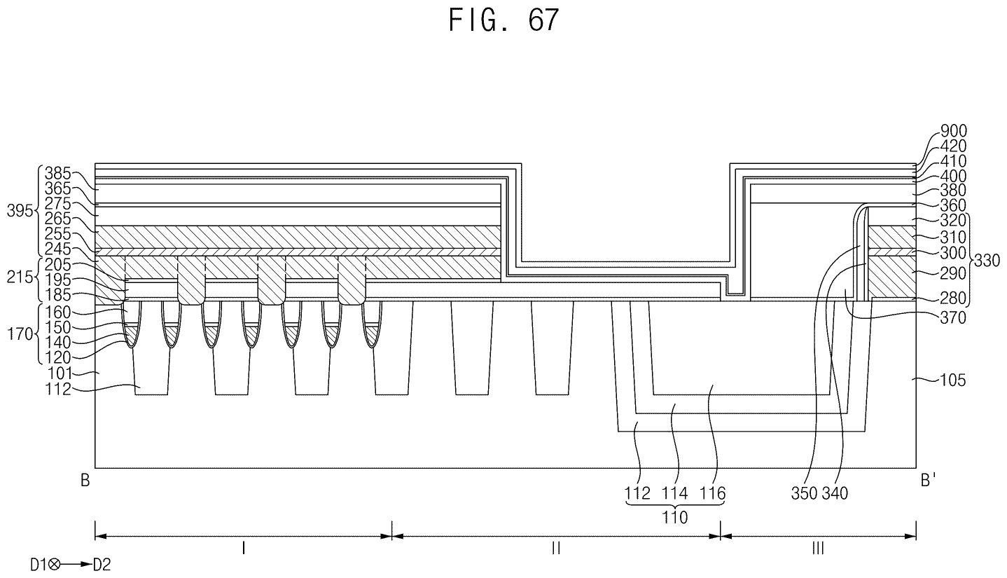

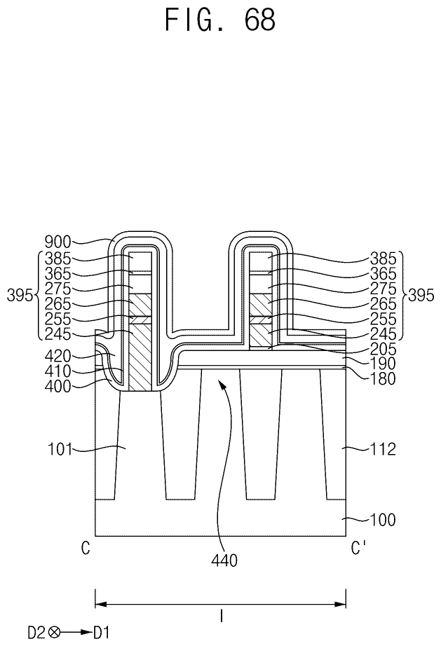

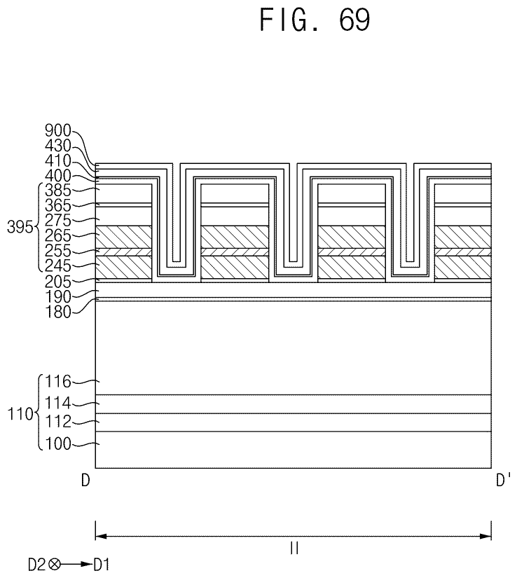

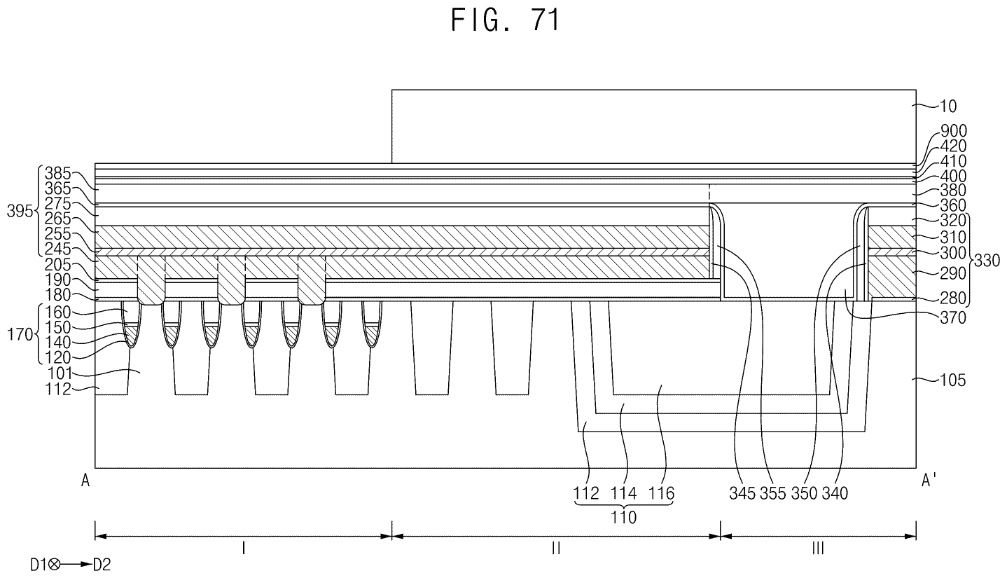

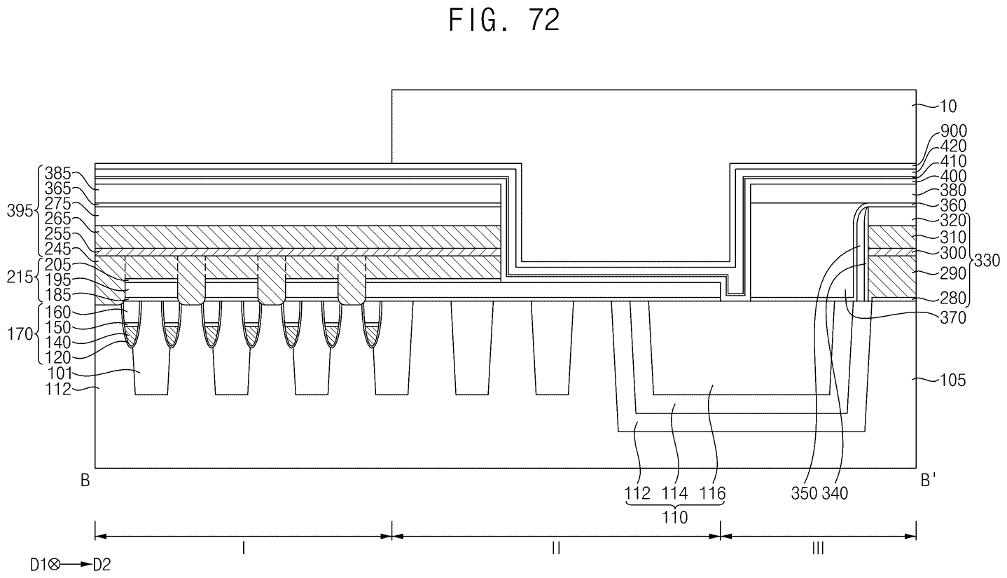

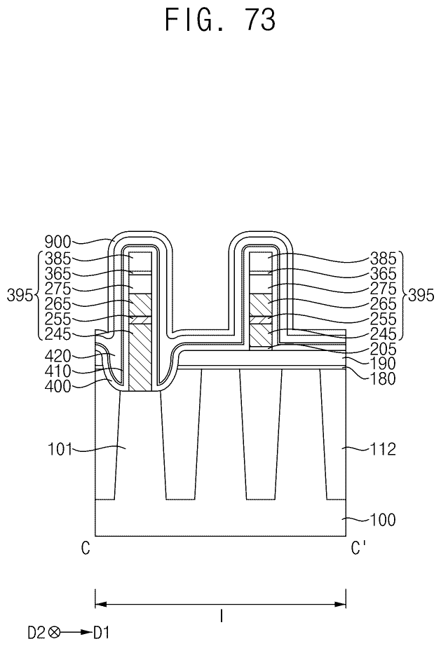

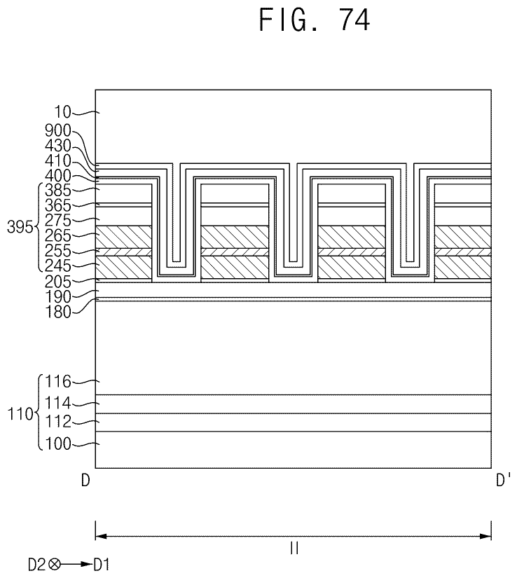

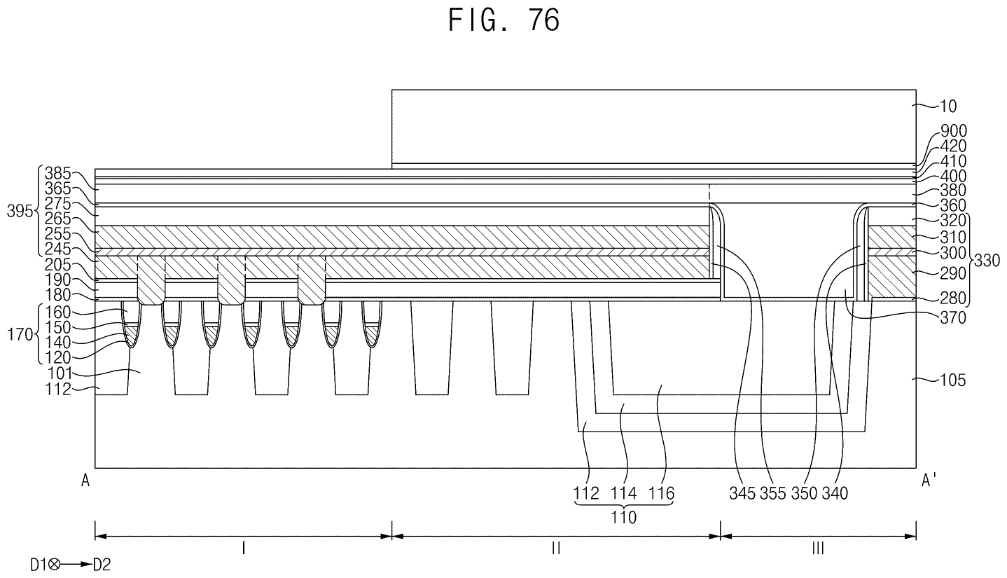

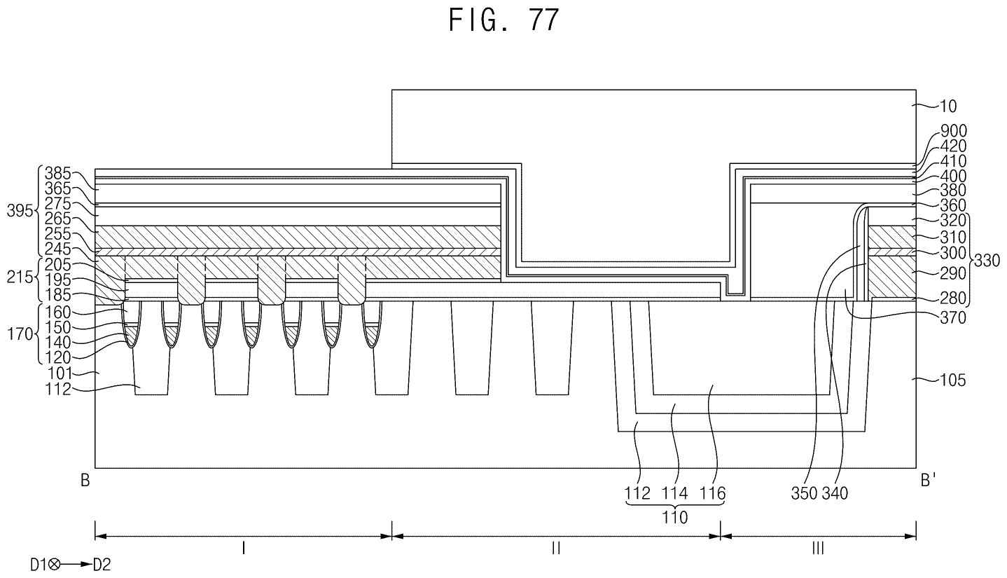

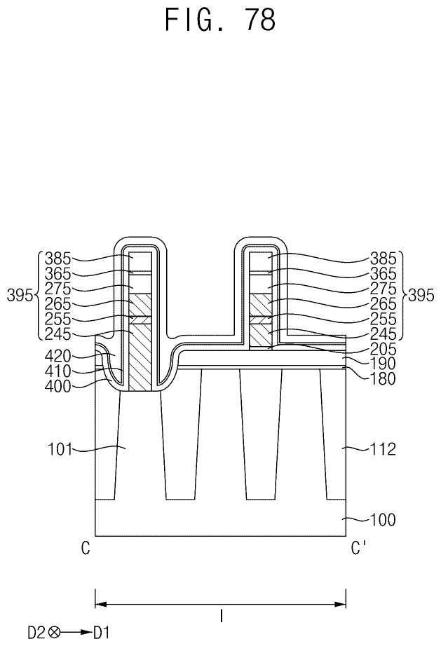

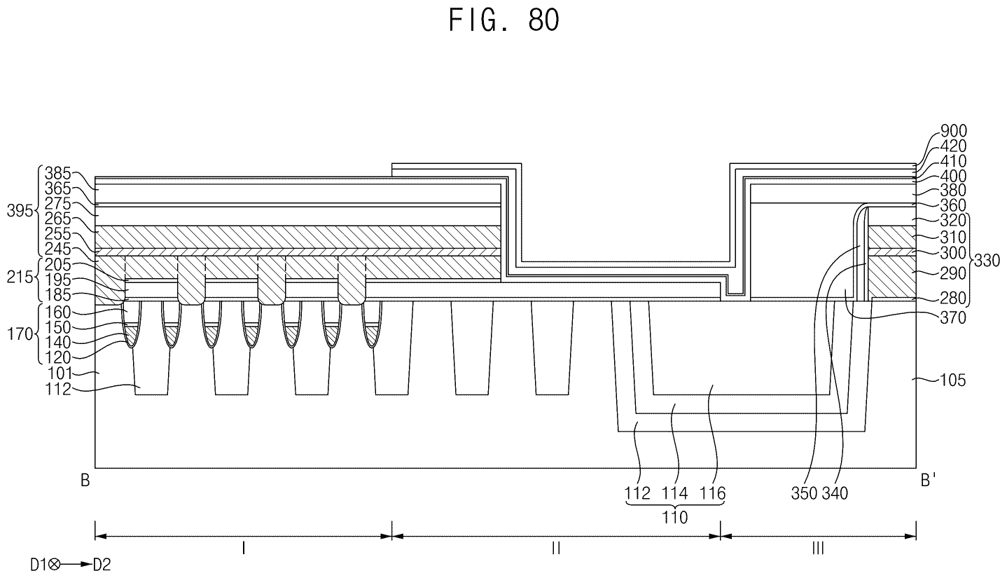

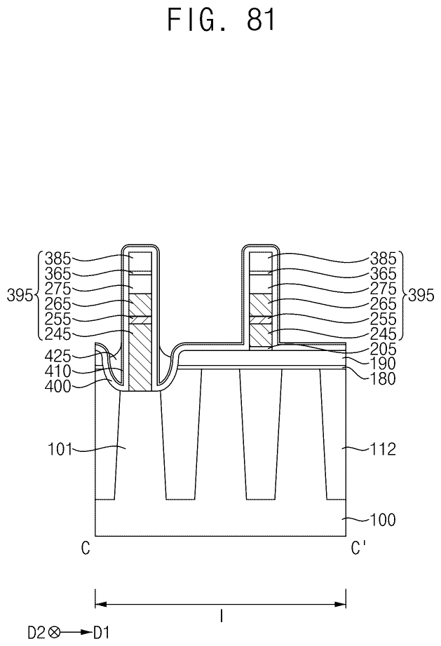

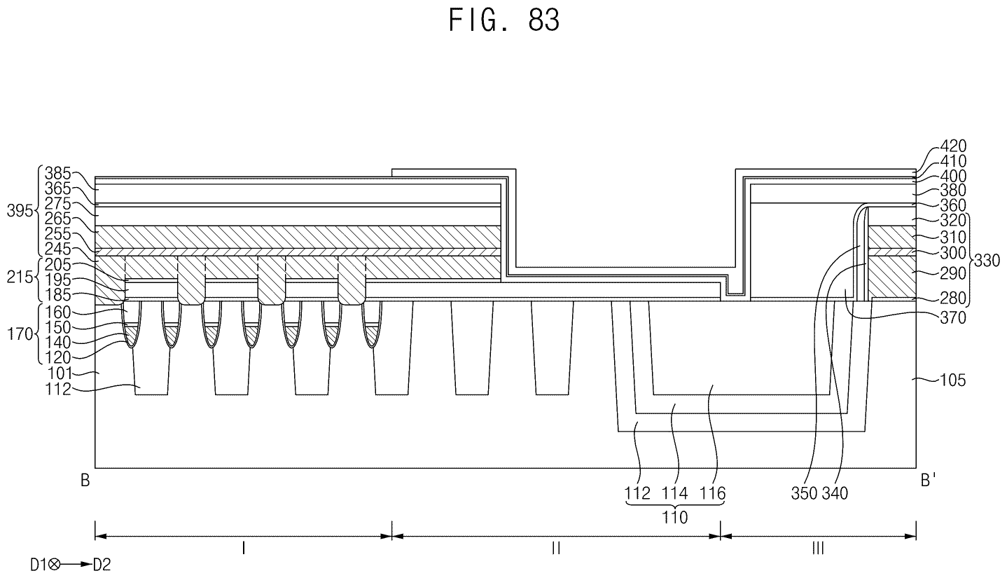

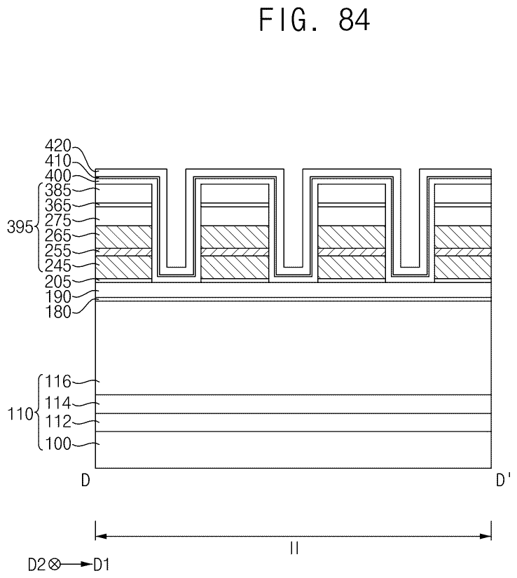

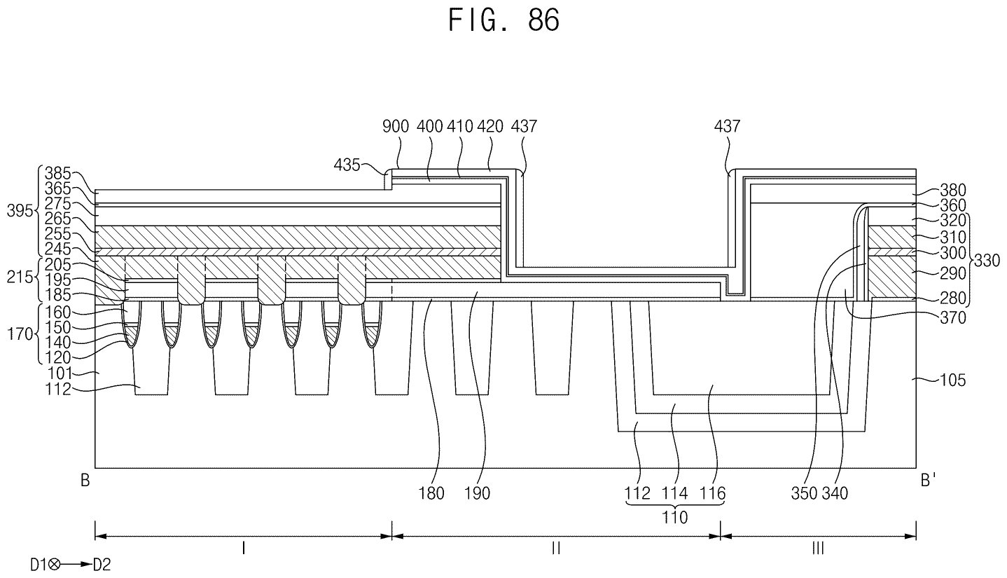

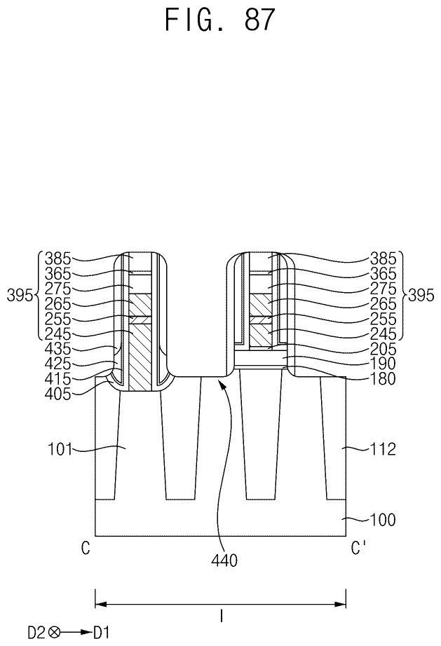

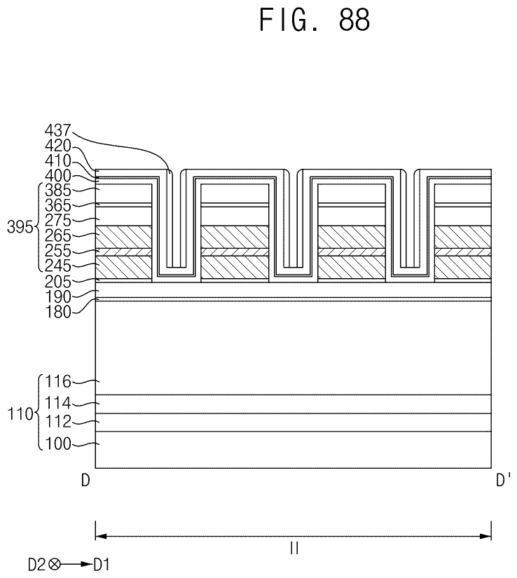

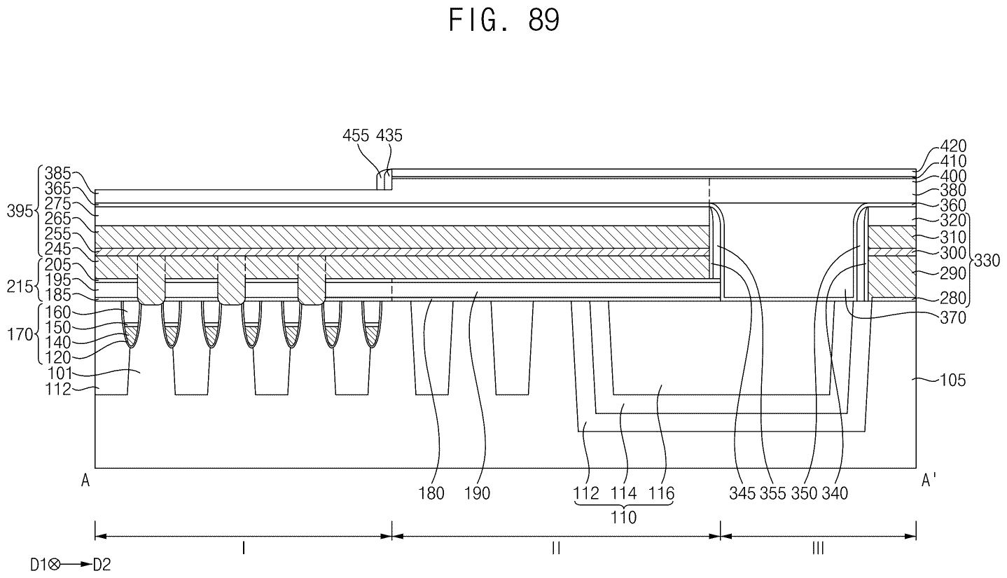

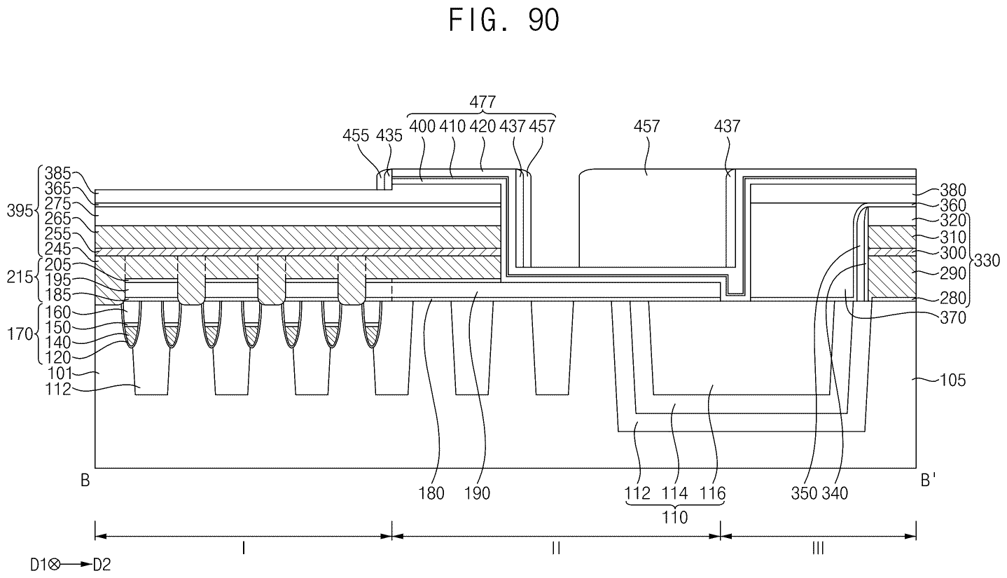

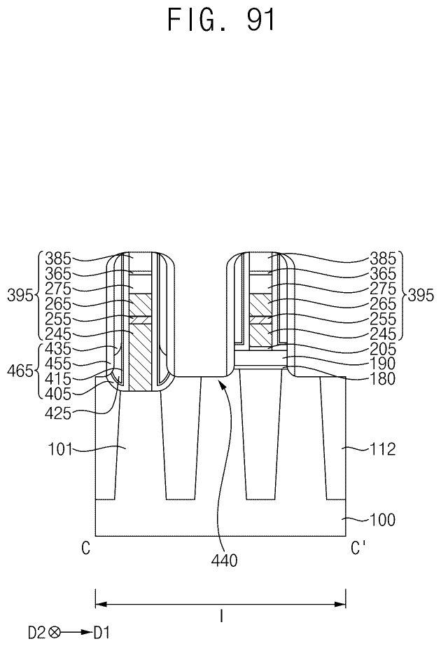

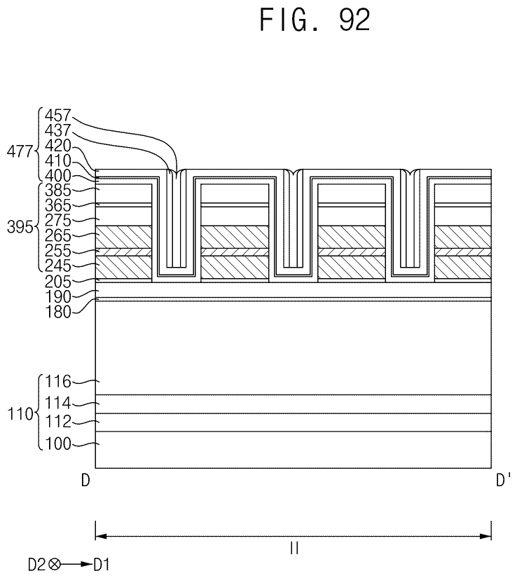

FIGS. 65 to 92 are plan views and cross-sectional views illustrating a method of manufacturing a semiconductor device according to various example embodiments. Specifically, FIGS. 65, 70 and 75 are the plan views, FIGS. 66, 71, 76, 79, 82, 85 and 89 are cross-sectional views taken along lines A-A′ of corresponding plan views, respectively, FIGS. 67, 72, 77, 80, 83, 86 and 90 are cross-sectional views taken along lines B-B′ of corresponding plan views, respectively, FIGS. 68, 73, 78, 81, 87 and 91 are cross-sectional views taken along lines C-C′ of corresponding plan views, respectively, and FIGS. 69, 74, 84, 88 and 92 are cross-sectional views taken along lines D-D′ of corresponding plan views, respectively. This method may include processes substantially the same as or similar to those illustrated with reference to FIGS. 1 to 64, and thus repeated explanations thereof are omitted herein.

Referring to FIGS. 65 to 69, processes substantially the same as or similar to those illustrated with reference to FIGS. 1 to 28 may be performed. Thereafter, a sacrificial spacer layer 900 may be formed on the fourth insulation layer 420. The sacrificial spacer layer 900 may include an oxide, e.g., silicon oxide.

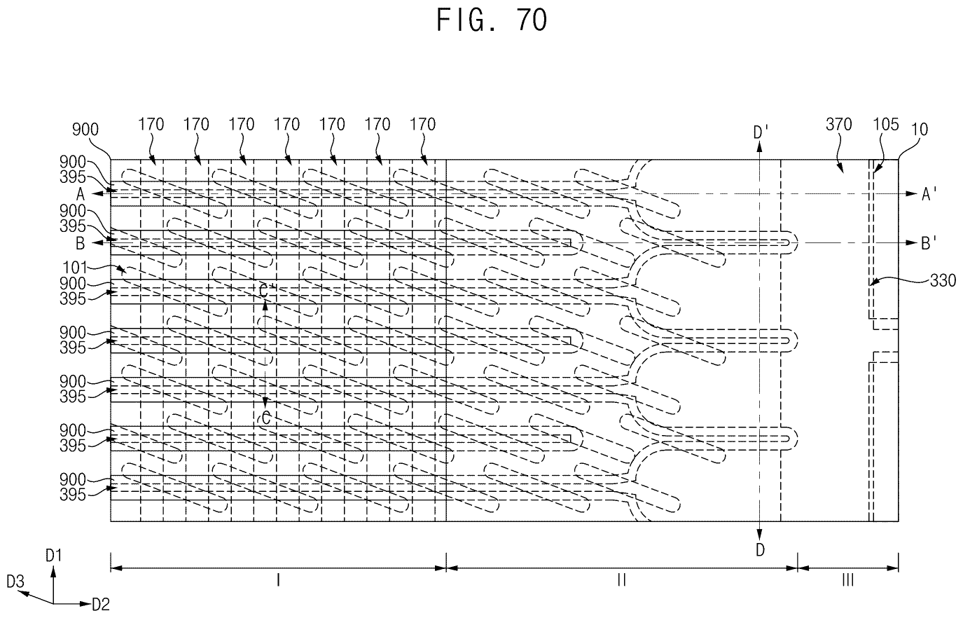

Referring to FIGS. 70 to 74, processes substantially the same as or similar to those illustrated with reference to FIGS. 33 to 37 may be performed.

That is, the photoresist structure 10 may be formed on the second and third regions II and III of the substrate 100. Accordingly, a portion of the sacrificial spacer layer 900 on the second and third regions II and III of the substrate 100, excluding a portion of the sacrificial spacer layer 900 on the first region I of the substrate 100, may be covered by the photoresist structure 10.

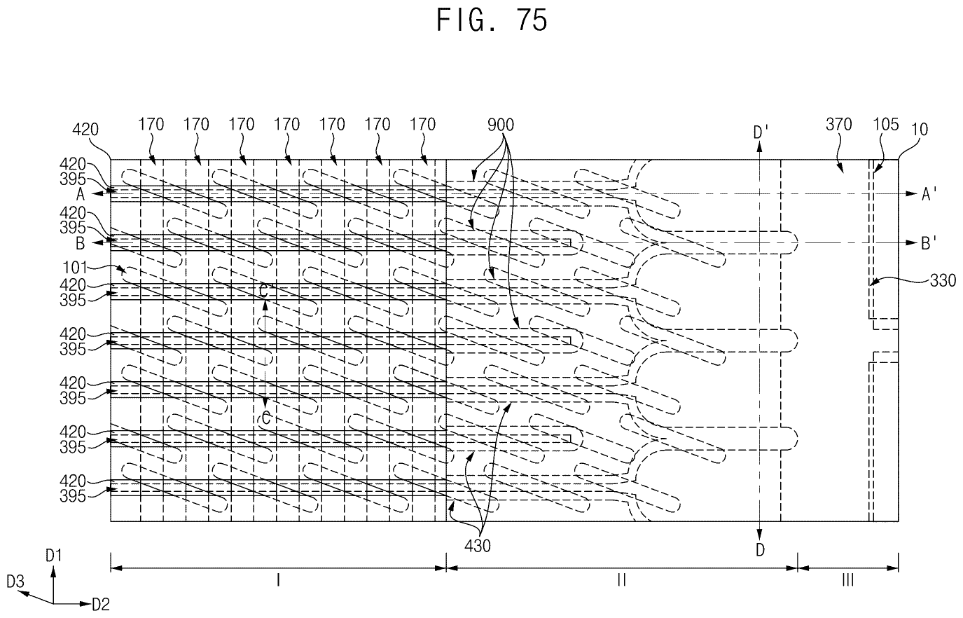

Referring to FIGS. 75 to 78, the exposed portion of the sacrificial spacer layer 900 on the first region I of the substrate 100 may be removed.

In various example embodiments, the sacrificial spacer layer 900 may be removed by a wet etch process using an etching solution including hydrofluoric acid (HF).

The portion of the sacrificial spacer layer 900 on the second and third regions II and III of the substrate 100 may be covered by the photoresist structure 10, and may be therefore unexposed to the wet etching process. Accordingly, the sacrificial spacer layer 900 may remain on the second and third regions II and III of the substrate 100 without being removed.

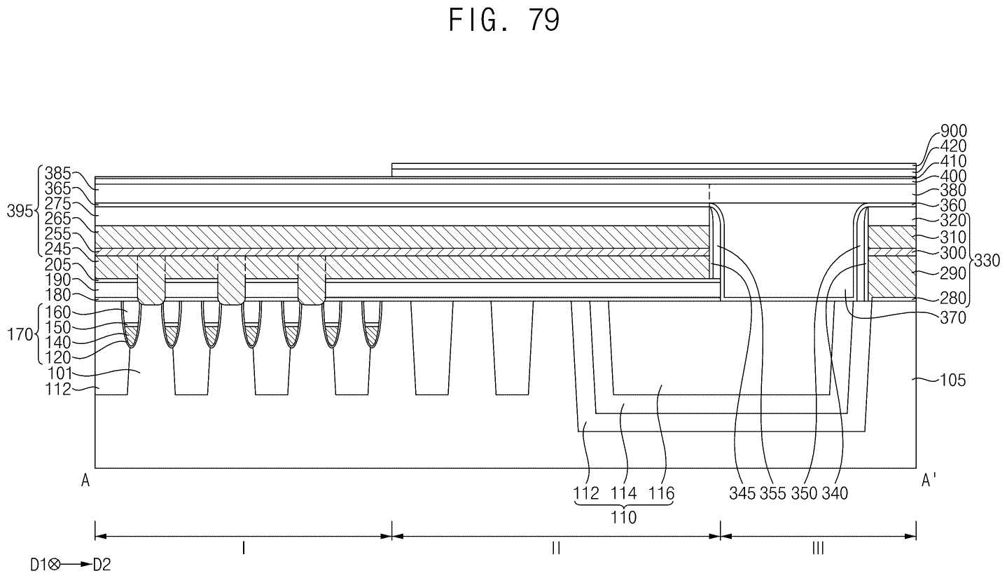

Referring to FIGS. 79 to 81, processes substantially the same as or similar to those illustrated with reference to FIGS. 43 to 47 may be performed.

That is, the photoresist structure 10 may be removed, thereby exposing the sacrificial spacer layer 900 on the second and third regions II and III of the substrate 100. In various example embodiments, the photoresist structure 10 may be removed by performing an ashing process and/or a strip process.

Processes substantially the same as or similar to those illustrated with reference to FIGS. 29 to 32 may be performed. Accordingly, most of the entire surface of the sixth spacer layer 410, that is, the entire surface except for the portion thereof in the first opening 230 may be exposed, and the portions of the fourth insulation layer 420 remaining in the first opening 230 may form the fourth insulation pattern 425.

Unlike the processes illustrated with reference to FIGS. 29 to 32, the portion of the fourth insulation layer 420 formed on the second and third regions II and III of the substrate 100 covered by the sacrificial spacer layer 900 may remain without being removed.

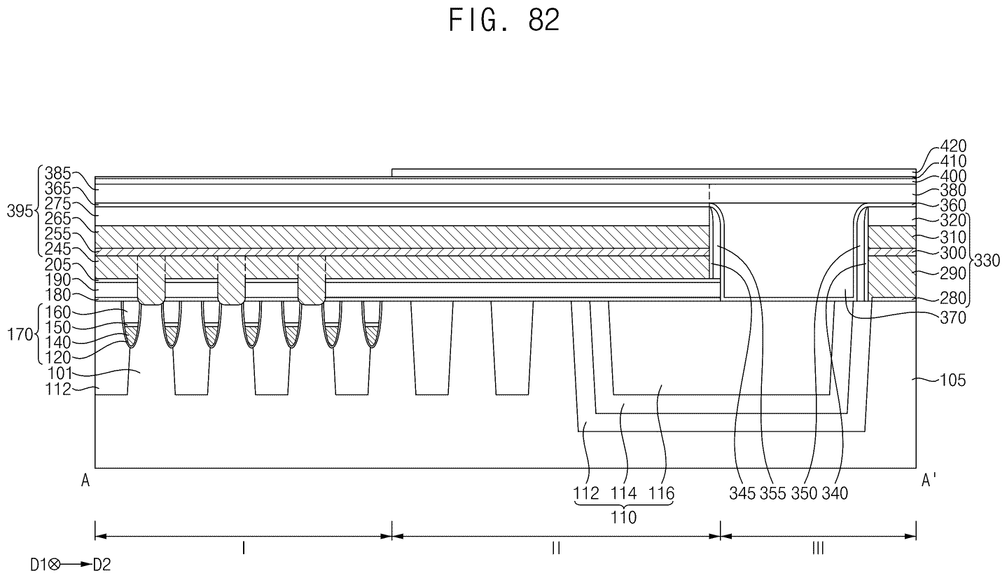

Referring to FIGS. 82 to 84, the portion of the sacrificial spacer layer 900 on the second and third regions II and III of the substrate 100 may be removed, and accordingly, the remaining portion of the fourth insulation layer 420 on the second and third regions II and III may be exposed.

In various example embodiments, the sacrificial spacer layer 900 may be removed by a wet etch process using an etching solution including hydrofluoric acid (HF).

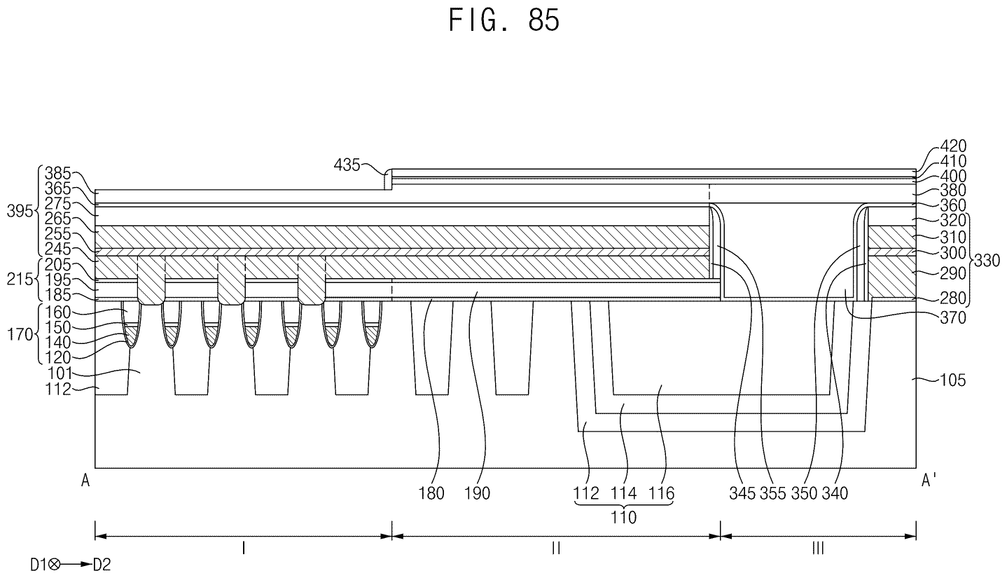

Referring to FIGS. 85 to 88, processes substantially the same as or similar to those illustrated with reference to FIGS. 33 to 42 may be performed.

The seventh spacer layer 430 may be formed on the surface of the sixth spacer layer 410 and the upper surface of the fourth insulation pattern 425 on the first region I of the substrate 100 and the upper surface of the fourth insulation pattern 425 on the second and third region II and III of the substrate 100, and the seventh spacer layer 430 may be anisotropically etched. Accordingly, the seventh spacer 435 may be formed at the sidewall of the bit line structure 395 on the first region I of the substrate 100 on the surface of the sixth spacer layer 410 and the upper surface of the fourth insulation layer 420.

Unlike processes illustrated with reference to FIGS. 33 to 42, the photoresist structure 10 may not be formed on the second and third regions II and III of the substrate 100. Accordingly, the seventh spacer layer 430 may be transformed to a tenth spacer 437 covering the sidewalls of the bit line structure 395 on the second and third regions II and III of the substrate 100 by the anisotropic etching process.

Referring to FIGS. 89 to 92, processes substantially the same as or similar to those illustrated with reference to FIGS. 43 to 47 may be performed.

That is, the eighth spacer 455 covering the outer sidewall of the seventh spacer 435 that is formed from the sidewall in the first direction D1 of the bit line structure 395 on the first region I of the substrate 100, and the ninth spacer 457 covering an outer sidewall of the tenth spacer 437 that is formed from the sidewall of the bit line structure 395 on the second region II of the substrate 100 may be formed.

The fifth and sixth spacer layers 400 and 410, the fourth insulation layer 420 and the tenth and ninth spacers 437 and 457 sequentially stacked in the horizontal direction from the sidewall of the bit line structure 395 on the second region II of the substrate 100 may collectively from a fifth spacer structure 477.

In various example embodiments, compared to the third spacer structure 465 having a total of four layers, that is, the fifth to eighth spacers 405, 415, 435 and 455, the fifth spacer structure 477 may further include the fourth insulation layer 420 to have a total of five layers.

In the method of forming the semiconductor device, the fourth insulation layer 420 may be formed on the sidewall of the bit line structure 395, the photoresist structure 10 may be formed to cover the second and third region II and III of the substrate 100, and the fourth insulation layer 420 on the first region I of the substrate 100 may be etched to form the fourth insulation pattern 425. The fourth insulation layer 420 may remain on the second and third region II and III of the substrate 100. Accordingly, the remaining portion of the fourth insulation layer 420 may protect the right end of the second bit line structure during the anisotropic etching process of the seventh spacer layer 430.

While the present inventive concepts have been shown and described with reference to various example embodiments thereof, it will be understood by those of ordinary skill in the art that various changes in form and details may be made thereto without departing from the spirit and scope of the present inventive concepts as set forth by the following claims.

What is claimed is:

1. A semiconductor device comprising:
an active pattern on a substrate, the substrate including a cell array region and an extension region, the extension region being at opposite sides in a first direction of the cell array region;
a bit line structure extending in the first direction on the active pattern; and
a spacer structure on a sidewall of the bit line structure in a second direction, the second direction being perpendicular to the first direction, and
wherein a first thickness of a first portion of the spacer structure on the extension region of the substrate in the second direction is greater than a second thickness of a second portion of the spacer structure on the cell array region of the substrate in the second direction.

2. The semiconductor device of claim 1, wherein the spacer structure includes a first spacer, a second spacer, a third spacer, and a fourth spacer sequentially stacked in the second direction on the sidewall of the bit line structure in the second direction.

3. The semiconductor device of claim 2, wherein a third thickness of the third spacer of the first portion of the spacer structure in the second direction is greater than a fourth thickness of the third spacer of the second portion of the spacer structure in the second direction.

4. The semiconductor device of claim 2, wherein each of the first and fourth spacers includes an insulating nitride, and each of the second and third spacers includes an oxide.

5. The semiconductor device of claim 2, further comprising:
an insulation pattern on a lower outer sidewall of the second spacer, and
wherein the third and fourth spacers are on the insulation pattern.

6. The semiconductor device of claim 5, wherein the insulation pattern includes an insulating nitride.

7. The semiconductor device of claim 1, wherein the spacer structure includes
a first spacer, a second spacer, and a third spacer sequentially stacked in the second direction on the sidewall of the bit line structure in the second direction, and
each of the first and third spacers includes an insulating nitride, and the second spacer includes an oxide.

8. The semiconductor device of claim 1, wherein
a plurality of active patterns are spaced apart from each other in the first and second directions,
contact plug structures contact end portions of the active patterns, respectively, and
a width of each of the contact plug structures on the extension region of the substrate in the second direction is smaller than a width of each of the contact plug structures on the cell array region of the substrate in the second direction.

9. A semiconductor device comprising:
an active pattern on a substrate, the substrate including a cell array region and an extension region, the extension region being at opposite sides in a first direction of the cell array region;
a bit line structure extending in the first direction on the active pattern; and
a spacer structure on a sidewall of the bit line structure in a second direction, the second direction being perpendicular to the first direction, and
wherein a first portion of the spacer structure on the extension region of the substrate includes a first spacer, a second spacer, a third spacer, an insulation layer, and a fourth spacer sequentially stacked on the sidewall of the bit line structure in the second direction, and
a second portion of the spacer structure on the cell array region of the substrate includes the first spacer, the second spacer, the third spacer, and the fourth spacer sequentially stacked on the sidewall of the bit line structure in the second direction.

10. The semiconductor device of claim 9, further comprising:
an insulation pattern on a lower outer sidewall of the second spacer on the cell array region of the substrate,
wherein the third and fourth spacers are on the insulation pattern, and
the insulation layer and the insulation pattern include a same material with each other.

11. The semiconductor device of claim 10, wherein each of the first and fourth spacers, the insulation layer, and the insulation pattern includes an insulating nitride, and each of the second and third spacers includes an oxide.

12. A semiconductor device comprising:
active patterns on a substrate, the substrate including a cell array region and an extension region, the extension region being at opposite sides in a first direction of the cell array region;
the active patterns spaced apart from each other in the first direction and a second direction, the second direction being perpendicular to the first direction; and
bit line structures; and
each of the bit line structures including
an extension portion extending in the first direction on the cell array region of the substrate and overlapping central portions of the active patterns arranged in the first direction,
a pad portion on the extension region of the substrate, the pad portion contacting an end of the extension portion in the first direction,
spacer structures on sidewalls of the bit line structures, respectively, and
contact plug structures on end portions of the active patterns, respectively, and
wherein a width of the pad portion of each of the bit line structures in the second direction is greater than a width of the extension portion of each of the bit line structures in the second direction, and
a first thickness of a first portion of each of the spacer structures on the extension region of the substrate in the second direction is greater than a second thickness of a second portion of each of the spacer structures on the cell array region of the substrate in the second direction.

13. The semiconductor device of claim 12, wherein
a first end and a second end of the extension portion of each of the bit line structures are at opposite sides in the first direction of the extension portion,
the pad portion of a first bit line structure of the bit line structures contacts the first end of the extension portion, and
the pad portion of a second bit line structure of the bit line structures contacts the second end of the extension portion, and
wherein the first and second bit line structures of the bit line structures are arranged alternately along the second direction.

14. The semiconductor device of claim 12, wherein a width of each of the contact plug structures on the cell array region of the substrate in the second direction is greater than a width of each of the contact plug structures on the extension region of the substrate in the second direction.

15. The semiconductor device of claim 12, wherein each of the spacer structures includes a first spacer, a second spacer, a third spacer, and a fourth spacer sequentially stacked in the second direction on a sidewall of each of the bit line structures in the second direction.

16. The semiconductor device of claim 15, wherein each of the first and fourth spacers includes an insulating nitride, and each of the second and third spacers includes an oxide.

17. The semiconductor device of claim 15, wherein a first thickness of a first portion of the third spacer of the spacer structure on the extension region of the substrate in the second direction is greater than a second thickness of a second portion of the third spacer of the spacer structure on the cell array region of the substrate in the second direction.

18. The semiconductor device of claim 15, wherein the first portion of each of the spacer structures further includes an insulation layer between the second and third spacers.

19. The semiconductor device of claim 18, wherein
the second portion of each of the spacer structures further includes an insulation pattern at a lower outer sidewall of the second spacer,
the third and fourth spacers of each of the spacer structures are on the insulation pattern, and
the insulation layer and the insulation pattern include a same material.

20. The semiconductor device of claim 19, wherein the insulation layer and the insulation pattern include an insulating nitride.
